(19) United States
(12) Patent Application Publication
(10) Pub. No.: US 2026/0156823 A1
(43) Pub. Date: Jun. 4, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Kyungeun Park, Suwon-si (KR); Wonho Chang, Suwon-si (KR); Junghoon Jun, Suwon-si (KR); Jeehoon Han, Suwon-si (KR)

(21) Appl. No.: 19/295,222

(22) Filed: Aug. 8, 2025

(30) Foreign Application Priority Data
Dec. 2, 2024 (KR) 10-2024-0176364

(51) Int. Cl. H10B 43/27; H10B 41/27; H10B 41/41; H10B 43/40

(52) U.S. Cl. CPC H10B 43/27; H10B 41/27; H10B 41/41; H10B 43/40

(57) ABSTRACT

A semiconductor device includes a plate layer; gate electrodes stacked in a vertical direction and extending to different lengths, and each including a pad region; interlayer insulating layers disposed alternately with the gate electrodes; contact plugs extending through the pad region; dummy vertical structures extending through the gate electrodes and the interlayer insulating layers in the second region and being spaced apart from the contact plugs; contact insulating structures disposed alternately with the interlayer insulating layers and surrounding the contact plugs. The pad region includes a first pad region penetrated by a first contact plug of the contact plugs. The dummy vertical structures include a first dummy vertical structure adjacent to the first contact plug. The contact insulating structures include first contact insulating structures in contact with the first contact plug and the first dummy vertical structure at the first pad region.

### CROSS-REFERENCE TO RELATED APPLICATION(S)

This application claims benefit of priority to Korean Patent Application No. 10-2024-0176364 filed on Dec. 2, 2024 in the Korean Intellectual Property Office, the disclosure of which is incorporated herein by reference in its entirety.

### BACKGROUND

A semiconductor device that is capable of storing high-capacity data in a data storage system has been desired. Accordingly, a method for increasing data storage capacity of a semiconductor device has been researched. For example, to increase integration density of a semiconductor device, a semiconductor device including memory cells arranged three-dimensionally, instead of two-dimensionally, has been suggested.

### SUMMARY

An example implementation of the present disclosure is to provide a semiconductor device having improved reliability, and a data storage system including the same.

According to an example implementation of the present disclosure, a semiconductor device includes a first semiconductor structure including a substrate, circuit devices on the substrate, and circuit interconnections on the circuit devices; and a second semiconductor structure on the first semiconductor structure, the second semiconductor structure having a first region and a second region, wherein the second semiconductor structure includes: a plate layer; gate electrodes stacked and spaced apart from each other on the plate layer in a vertical direction perpendicular to an upper surface of the plate layer, the gate electrodes extending to different lengths in a first direction intersecting the vertical direction in the second region, and each of the gate electrodes including a pad region, an upper surface of the pad region being exposed; interlayer insulating layers disposed alternately with the gate electrodes; a channel structure extending through the gate electrodes and the interlayer insulating layers in the first region, the channel structure extending in the vertical direction; contact plugs extending through the pad region of each of the gate electrodes in the second region, the contact plugs extending in the vertical direction, and the contact plugs electrically connecting the gate electrodes to at least one corresponding circuit interconnection of the circuit interconnections; dummy vertical structures extending through the gate electrodes and the interlayer insulating layers in the second region, the dummy vertical structures extending in the vertical direction and being spaced apart from the contact plugs in a horizontal direction; and contact insulating structures disposed alternately with the interlayer insulating layers, the contact insulating structures being at corresponding pad regions of the gate electrodes, the contact insulating structures surrounding the contact plugs, wherein the pad region of each of the gate electrodes includes a first pad region, and a first contact plug of the contact plugs extends through the first pad region, wherein the dummy vertical structures include a first dummy vertical structure adjacent to the first contact plug, and wherein the contact insulating structures include first contact insulating structures in contact with the first contact plug and the first dummy vertical structure, the first contact insulating structures being at the first pad region.

According to an example implementation of the present disclosure, a semiconductor device includes a stack pattern having a memory cell array region and a staircase region; a stack structure extending from the memory cell array region to the staircase region, the stack structure being on the stack pattern, wherein the stack structure includes interlayer insulating layers and gate electrodes disposed alternately in a vertical direction, and the gate electrodes include gate contact pads, the gate contact pads defining a staircase in the staircase region; a channel structure extending through the stack structure in the memory cell array region in the vertical direction; a first contact plug extending through the gate electrodes and the interlayer insulating layers in the staircase region; a first dummy vertical structure extending through the gate electrodes and the interlayer insulating layers in the staircase region, the first dummy vertical structure being adjacent to the first contact plug; first contact insulating structures disposed alternately with the interlayer insulating layers, the first contact insulating structures surrounding the first contact plug; and first dummy insulating structures disposed alternately with the interlayer insulating layers, the first dummy insulating structures surrounding the first dummy vertical structure, wherein the first contact insulating structures are spaced apart from the first dummy insulating structures, wherein each of the first dummy insulating structures includes a first dummy insulating pattern surrounding a first portion of the first dummy vertical structure, a second dummy insulating pattern surrounding a second portion of the first dummy vertical structure, the second portion of the first dummy vertical structure extending from the first portion, and a dummy insulating liner surrounding the first dummy insulating pattern and the second dummy insulating pattern, wherein the first dummy insulating pattern includes a first insulating material, and wherein the second dummy insulating pattern includes a second insulating material different from the first insulating material.

According to an example implementation of the present disclosure, a data storage system includes a semiconductor storage device comprising: a first semiconductor structure including circuit devices and circuit interconnections electrically connected to the circuit devices, a second semiconductor structure on the first semiconductor structure, the second semiconductor structure including a first region and a second region, and an input/output pad electrically connected to the circuit devices; and a controller electrically connected to the semiconductor storage device through the input/output pad, the controller electrically being configured to control the semiconductor storage device, wherein the second semiconductor structure includes: a plate layer; gate electrodes stacked and spaced apart from each other in a vertical direction on an upper surface of the plate layer, the gate electrodes extending to different lengths in a first direction intersecting the vertical direction in the second region, and each of the gate electrodes including a pad region, an upper surface of the pad region being exposed; interlayer insulating layers disposed alternately with the gate electrodes; channel structures extending through the gate electrodes and the interlayer insulating layers in the first region, the channel structures extending in the vertical direction; contact plugs extending through the pad region of each of the gate electrodes in the second region, the contact plugs extending in the vertical direction, the contact plugs electrically connecting the gate electrodes to at least one corresponding circuit interconnection of the circuit interconnections; dummy vertical structures extending through the gate electrodes and the interlayer insulating layers in the second region, the dummy vertical structures extending in the vertical direction and being spaced apart from the contact plugs in a horizontal direction intersecting the vertical direction; and contact insulating structures disposed alternately with the interlayer insulating layers, the contact insulating structures being at corresponding pad regions of the gate electrodes, the contact insulating structures surrounding the contact plugs, wherein the pad region of each of the gate electrodes includes a first pad region, and a first contact plug of the contact plugs extends through the first pad region, wherein the dummy vertical structures include a first dummy vertical structure adjacent to the first contact plug, and wherein each of the contact insulating structures includes a first contact insulating pattern in contact with the first contact plug and a first portion of the first dummy vertical structure at the first pad region, and second contact insulating patterns in contact with second portions of the first dummy vertical structure, the second portions of the first dummy vertical structure being connected to the first portion of the first dummy vertical structure.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a plan diagram illustrating a semiconductor device in example implementations of the present disclosure;

FIG. 1B is a cross-sectional diagram illustrating a semiconductor device taken along line I-I′ in FIG. 1A according to an example implementation of the present disclosure;

FIG. 1C is a cross-sectional diagram illustrating a semiconductor device taken along line II-II′ in FIG. 1A according to an example implementation of the present disclosure;

FIG. 1D is a cross-sectional diagram illustrating a semiconductor device taken along line III-III′ in FIG. 1A according to an example implementation of the present disclosure;

FIG. 2 is an enlarged diagram illustrating region C of the semiconductor device in FIG. 1A;

FIG. 3 is an enlarged diagram illustrating region A of the semiconductor device in FIG. 1A;

FIG. 4 is a cross-sectional diagram illustrating a semiconductor device taken along line A-A′ in FIG. 3 according to an example implementation of the present disclosure;

FIG. 5 is an enlarged diagram illustrating region B of the semiconductor device in FIG. 1A;

FIG. 6A is a cross-sectional diagram illustrating a semiconductor device taken along line B-B′ in FIG. 5 according to an example implementation of the present disclosure;

FIG. 6B is a cross-sectional diagram illustrating a semiconductor device taken along line B-B′ in FIG. 5 according to another example implementation of the present disclosure;

FIG. 7 is an enlarged diagram illustrating region B of the semiconductor device in FIG. 1A according to another example implementation of the present disclosure;

FIGS. 8 to 10 are cross-sectional diagrams illustrating a method of manufacturing a semiconductor device according to an example implementation of the present disclosure;

FIGS. 11A to 18B are diagrams illustrating a method of manufacturing a semiconductor device with respect to region B of FIG. 1A according to an example implementation of the present disclosure;

FIG. 19 is a cross-sectional diagram illustrating a semiconductor device taken along line I-I′ in FIG. 1A according to an example implementation of the present disclosure; and

FIG. 20 is a diagram illustrating a data storage system including a semiconductor device in example implementations of the present disclosure.

### DETAILED DESCRIPTION

Hereinafter, implementations of the present disclosure will be described as follows with reference to the accompanying drawings.

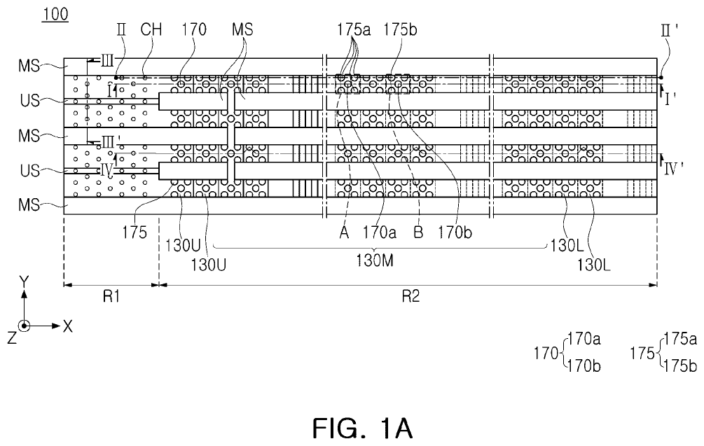

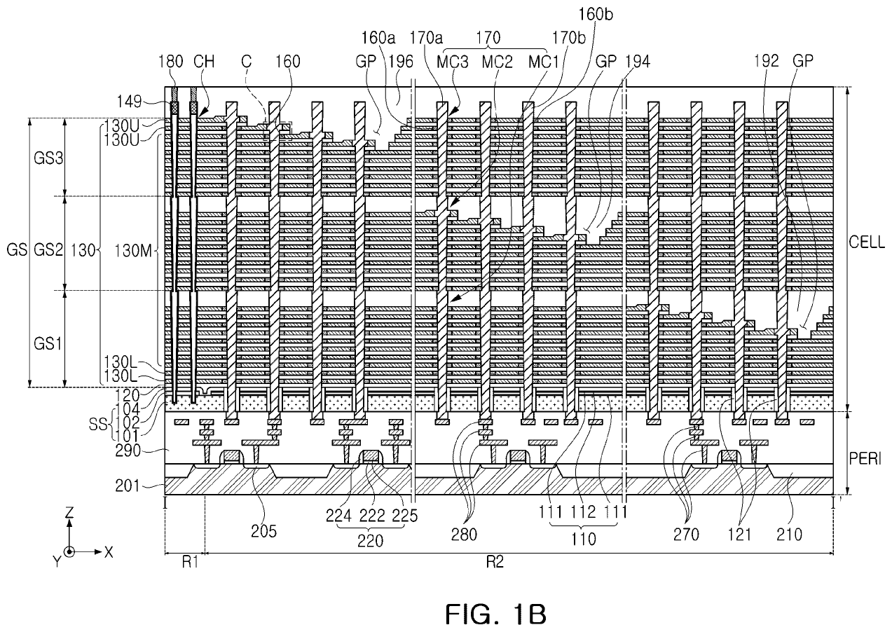

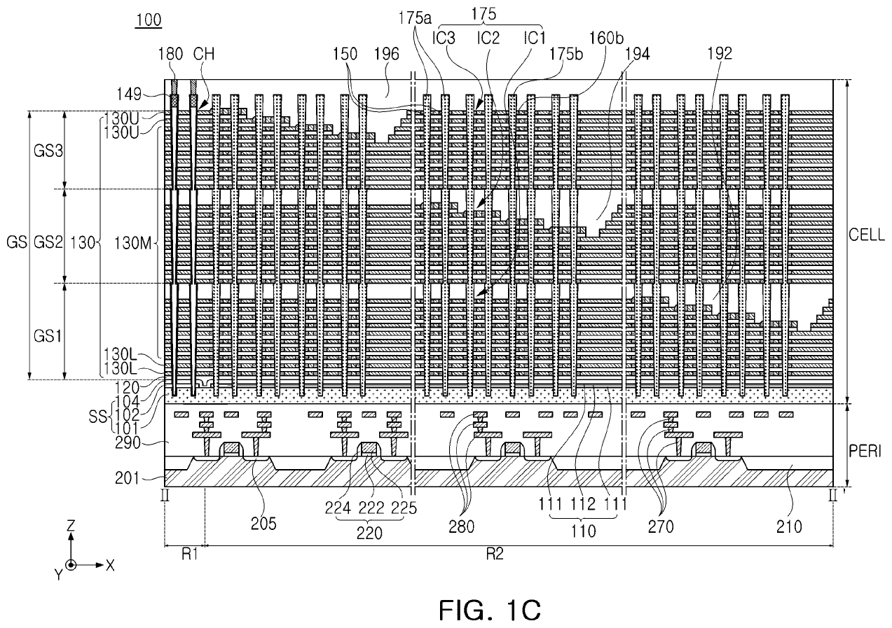

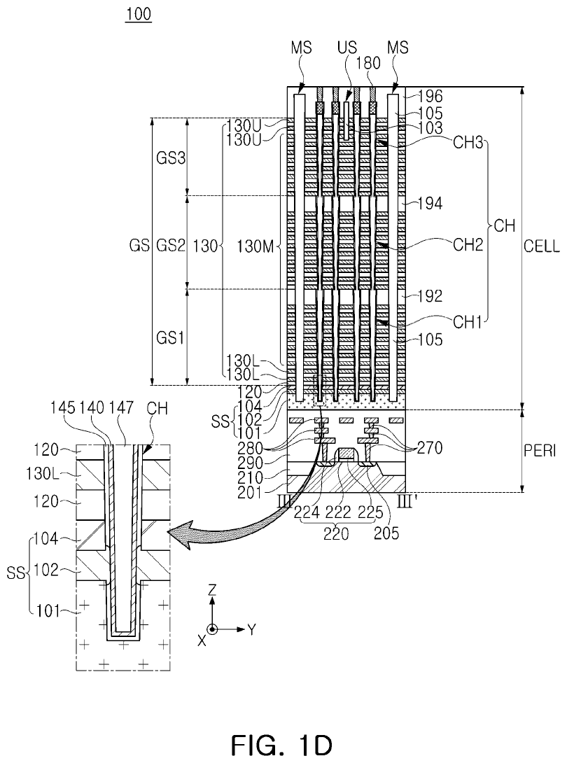

FIG. 1A is a plan diagram illustrating a semiconductor device in example implementations. FIG. 1B is a cross-sectional diagram illustrating a semiconductor device taken along line I-I′ in FIG. 1A according to an example implementation. FIG. 1C is a cross-sectional diagram illustrating a semiconductor device taken along line II-II′ in FIG. 1A according to an example implementation. FIG. 1D is a cross-sectional diagram illustrating a semiconductor device taken along line III-III′ in FIG. 1A according to an example implementation.

Referring to FIGS. 1A, 1B, 1C, and 1D, a semiconductor device 100 may include a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. In another example, the memory cell region CELL may be disposed below the peripheral circuit region PERI.

The peripheral circuit region PERI may include a substrate 201, impurity regions 205 in the substrate 201, device isolation layers 210, circuit devices 220 disposed on the substrate 201, a peripheral region insulating layer 290, a circuit contact plug 270, and circuit interconnection lines 280.

The substrate 201 may have an upper surface extending in the first direction (X-direction) and the second direction (Y-direction). The substrate 201 may have an active region defined by the device isolation layers 210. The impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 220 may include a planar transistor. Each of the circuit devices 220 may include a circuit gate dielectric layer 222, a spacer layer 224, and a circuit gate electrode 225. On both sides of the circuit gate electrode 225, the impurity regions 205 may be disposed in the substrate 201 as source/drain regions.

The peripheral region insulating layer 290 may be disposed on the circuit device 220 on the substrate 201. The peripheral region insulating layer 290 may include a plurality of insulating layers formed in different processes. The peripheral region insulating layer 290 may be formed of an insulating material.

The circuit contact plugs 270 and the circuit interconnection lines 280 may form a circuit interconnection structure electrically connected to the circuit devices 220 and the impurity regions 205. The circuit contact plugs 270 may have a cylindrical shape, and the circuit interconnection lines 280 may have a line shape. An electrical signal may be applied to the circuit device 220 by the circuit contact plugs 270 and the circuit interconnection lines 280. In the region not illustrated, the circuit contact plugs 270 may also be connected to the circuit gate electrode 225. The circuit interconnection lines 280 may be connected to the circuit contact plugs 270, may have a line shape, and may be disposed in a plurality of layers. The circuit contact plugs 270 and the circuit interconnection lines 280 may include a conductive material, for example, tungsten (W), copper (Cu), aluminum (Al), and each component may further include a diffusion barrier. In example implementations, the number of layers of the circuit contact plugs 270 and the circuit interconnection lines 280 may be varied.

The memory cell region CELL may include a first region R1 and a second region R2. The memory cell region CELL may include a source structure SS including a plate layer 101, gate electrodes 130 stacked on the source structure SS and included in the gate structure GS, interlayer insulating layers 120 alternately stacked with the gate electrodes 130 and included in the gate structure GS, channel structures CH disposed to penetrate the gate structure GS in the first region R1, isolation regions MS (also referred to as isolation structure in the present disclosure) extending by penetrating the gate structure GS, auxiliary isolation regions US disposed to penetrate a portion disposed in an upper portion of the gate electrodes 130, and contact plugs 170 connected to the gate electrodes 130 and extending vertically in the second region R2, and dummy vertical structures 175 disposed to penetrate the gate structure GS and disposed around the contact plugs 170. In an example, the memory cell region CELL may further include a horizontal insulating layer 110 disposed below the gate electrodes 130 in the second region R2, substrate insulating layers 121 disposed to penetrate the plate layer 101, studs 180 on the channel structure CH and the contact plugs 170, and first to third cell region insulating layers 192, 194, and 196 covering the gate electrodes 130.

In the memory cell region CELL, in the first region R1, the gate electrodes 130 may be vertically stacked and the channel structure CH may be disposed, and the memory cells may be disposed in the first region R1. In the second region R2, the gate electrodes 130 may extend to different lengths and may form gate pad regions GP, and the second region R2 may be configured to electrically connect the memory cells to the peripheral circuit region PERI. The second region R2 may be disposed at least in one direction, for example, in the first direction (X-direction) on at least one end of the first region R1. In example implementations, the first region R1 may be referred to as a memory cell array region, and the second region R2 may be referred to as a staircase region.

The source structure SS may include a plate layer 101, a first horizontal conductive layer 102, and a second horizontal conductive layer 104 stacked in order in the first region R1. However, in example implementations, the number of conductive layers included in the source structure SS may be varied. In example implementations, the source structure SS may be referred to as a stack pattern.

The plate layer 101 may have a plate shape and may function as at least a portion of a common source line of the semiconductor device 100. The plate layer 101 may have an upper surface extending in the first direction (X-direction) and the second direction (Y-direction). The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer, such as a polycrystalline silicon layer, or an epitaxial layer.

The first and second horizontal conductive layers 102 and 104 may be stacked in order on an upper surface of the plate layer 101 in the first region R1. The first horizontal conductive layer 102 may not extend to the second region R2, and the second horizontal conductive layer 104 may extend to the second region R2. The first horizontal conductive layer 102 may function as a portion of a common source line of the semiconductor device 100, for example, may function as a common source line together with the plate layer 101. As illustrated in FIG. 1D, the first horizontal conductive layer 102 may be directly connected to the channel layer 140 around the channel layer 140. The second horizontal conductive layer 104 may be in contact with the plate layer 101 at partial regions of the second region R2 in which the first horizontal conductive layer 102 and the horizontal insulating layer 110 are not disposed.

The first and second horizontal conductive layers 102 and 104 may include a semiconductor material, for example, may include polycrystalline silicon. In this case, at least the first horizontal conductive layer 102 may be a layer doped with impurities of conductivity-type the same as that of the plate layer 101, and the second horizontal conductive layer 104 may be a doped layer or a layer including impurities diffused from the first horizontal conductive layer 102. However, the material of the second horizontal conductive layer 104 is not limited to a semiconductor material, and may also be replaced with an insulating layer.

The horizontal insulating layer 110 may be disposed on the plate layer 101 at the same level as the first horizontal conductive layer 102 in at least a portion of the second region R2. The horizontal insulating layer 110 may include first and second horizontal insulating layers 111 and 112 alternately stacked on the second region R2 of the plate layer 101. The horizontal insulating layer 110 may be layers remaining after a portion is replaced with the first horizontal conductive layer 102 in a process of manufacturing the semiconductor device 100.

The horizontal insulating layer 110 may include silicon oxide, silicon nitride, silicon carbide, or silicon oxynitride. The first horizontal insulating layer 111 and the second horizontal insulating layer 112 may include different insulating materials. For example, the first horizontal insulating layers 111 may be formed of the same material as a material of the interlayer insulating layers 120, and the second horizontal insulating layer 112 may be formed of a material different from a material of the interlayer insulating layers 120.

The substrate insulating layers 121 may be disposed to penetrate the plate layer 101, the horizontal insulating layer 110, and the second horizontal conductive layer 104 in a portion of the second region R2. The substrate insulating layers 121 may further be disposed in the first region R1, for example, in a region in which a through-via extending from the memory cell region CELL to the peripheral circuit region PERI is disposed. An upper surface of the substrate insulating layer 121 may be coplanar with an upper surface of the second horizontal conductive layer 104. The substrate insulating layer 121 may include an insulating material, for example, silicon oxide, silicon nitride, silicon carbide, or silicon oxynitride.

The gate electrodes 130 may be vertically stacked and spaced apart from each other on the plate layer 101 and may be included in a gate structure GS together with interlayer insulating layers 120. The gate structure GS may include first, second and third stack structures GS1, GS2 and GS3, vertically stacked. However, in example implementations, the number of stack structures included in the gate structure GS may be varied. For example, the gate structure GS may include four or more stack structures, or may include a single stack structure or two stack structures. The number of the gate electrodes 130 included in each of the first, second and third stack structures GS1, GS2 and GS3 may be the same or different.

The gate electrodes 130 may include lower gate electrodes 130L forming gates of ground select transistors, memory gate electrodes 130M included in a plurality of memory cells, and upper gate electrodes 130U included in gates of string select transistors. The number of the memory gate electrodes 130M included in the memory cells may be determined depending on capacity of the semiconductor device 100. In example implementations, each of the number of the upper gate electrodes 130U and the number of the lower gate electrodes 130L may be 1 to 4 or more, and the upper and lower gate electrodes 130U and 130L may have a structure the same as or different from as the memory gate electrodes 130M. In example implementations, the gate electrodes 130 may further include gate electrodes 130 included in an erase transistor disposed adjacent to the upper gate electrodes 130U and/or the lower gate electrodes 130L and used in an erase operation using a gate induced drain leakage (GIDL) phenomenon. Also, a portion of the gate electrodes 130, for example, the memory gate electrodes 130M adjacent to the upper or lower gate electrodes 130U and 130L, may be dummy gate electrodes.

As illustrated in FIG. 1A, the gate electrodes 130 may be isolated from each other in the second direction (Y-direction) by isolation regions MS extending continuously from the first region R1 and the second region R2. The gate electrodes 130 may form one memory block between a pair of isolation regions MS, but the range of the memory block is not limited thereto. A portion of the gate electrodes 130, for example, the memory gate electrodes 130M, may form each layer in one memory block.

The gate electrodes 130 may be stacked vertically spaced apart from each other on the first region R1, may extend from the first region R1 to the second region R2 with different lengths and may form step structures in the form of a staircase in the gate pad regions GP. The gate pad regions GP may be defined as regions including gate pads connected to the contact plugs 170 of the gate electrodes 130.

As illustrated in FIG. 1B, the gate electrodes 130 may have a form in which the gate pad regions GP are removed from an upper portion of one of the first to third stack structures GS1, GS2, and GS3 by a predetermined depth. The gate pad regions GP may be disposed so as not to overlap each other in the third direction (Z-direction), which is the vertical direction. The gate electrodes 130 included in the second and third stack structures GS2 and GS3 on the gate pad regions GP of the first stack structure GS1 may extend horizontally. In the example implementation, the gate pad regions GP may be disposed in the order of the third stack structure GS3, the second stack structure GS2, and the first stack structure GS1 from the first region R1 in the first direction (X-direction). Only one gate pad region GP may be disposed in each of the first, second and third stack structures GS1, GS2, and GS3 as illustrated, or a plurality of gate pad regions GP may be disposed in each of the first, second, and third stack structures GS1, GS2, and GS3. However, the arrangement shape, arrangement order, and depth of the gate pad regions GP in the example implementations may be varied. In an example, the gate electrodes 130 may not be disposed on the gate pad regions GP.

The gate electrodes 130 may form first and second step structures in an asymmetrical shape in the first direction (X-direction) in each gate pad region GP. The first step structure may be a staircase structure relatively adjacent to the first region R1 and having a level decreasing in the first direction (X-direction), and the second step structure may be a staircase structure positioned relatively far from the first region R1 and having a level increasing in the first direction (X-direction). For example, a slope of the first step structure in each gate pad regions GP may be less than a slope of the second step structure in the second region R2. However, in some example implementations, the first and second step structures may have a symmetrical shape.

In the first step structure, the gate electrodes 130 may be connected to the contact plugs 170, and in the second step structure, the gate electrodes 130 may form a dummy region not connected to the contact plugs 170. In example implementations, a specific shape of the step structure, and the number of gate electrodes 130 forming each step structure are not limited to the example illustrated in FIG. 1B. In some example implementations, the gate electrodes 130 may be disposed to have step structures in the second direction (Y-direction) as well. The gate electrodes 130 may include contact regions (not illustrated) connected to the contact plugs 170. The contact regions may be regions of the gate electrode layer not covered by other gate electrodes in one stack structure, and may be defined as regions in which gate pads in contact with the contact plugs 170 in each of the stack structures GS disposed in the second region R2 are disposed.

The gate electrodes 130 may include a metal material, for example, tungsten (W). In example implementations, the gate electrodes 130 may include polycrystalline silicon or a metal silicide material. In example implementations, the gate electrodes 130 may further include a diffusion barrier, for example, the diffusion barrier may include tungsten nitride (WN), tantalum nitride (TaN), titanium nitride (TiN), or a combination thereof.

The interlayer insulating layers 120 may be disposed between the gate electrodes 130. The interlayer insulating layers 120 may also be disposed to be spaced apart from each other in the vertical direction and to extend in the first direction (X-direction) on the upper surface of the plate layer 101, similarly to the gate electrodes 130. In each of the first, second, and third stack structures GS1, GS2, and GS3, thicknesses of the interlayer insulating layers 120 may not be the same. In an example, at least a portion of the interlayer insulating layers 120 may have different thicknesses from other portions. Also, the number of interlayer insulating layers 120 may be varied from the illustrated example. The interlayer insulating layers 120 may include an insulating material such as silicon oxide or silicon nitride.

Each of the channel structures CH may form a memory cell string and may be spaced apart from each other in rows and columns on the plate layer 101 in the first region R1. The channel structures CH may be disposed in a grid pattern in the X-Y plane, or in a zigzag pattern in one direction. The channel structures CH may have a columnar shape and may have sloped side surfaces having a width decreasing toward the plate layer 101 depending on an aspect ratio. In example implementations, at least a portion of the channel structures CH disposed on an end of the first region R1 may be dummy channel structures.

Referring to FIG. 1D, each of the channel structures CH may include first, second, and third channel portions CH1, CH2, and CH3 stacked in the third direction (Z-direction). The first, second, and third channel portions CH1, CH2, and CH3 may penetrate the first, second, and third stack structures GS1, GS2, and GS3 of the gate structure GS, respectively. The channel structure CH may have a form in which the first channel portion CH1, the second channel portion CH2 of the upper portion of the first channel portion CH1, and the third channel portion CH3 of the upper portion of the second channel portion CH2 are connected to each other. The first, second, and third channel portions CH1, CH2, and CH3 may have a form in which a width of an upper surface of the channel portion disposed in a lower portion is greater than a width of a lower surface of the channel portion disposed in an upper portion in a connected region or an interfacial surface. The channel structure CH may have bent portions due to a difference in width at an interfacial surface between the first, second, and third channel portions CH1, CH2, and CH3. However, the number of the channel portions stacked in the third direction (Z-direction) in the channel structure CH may be varied in example implementations. The first channel portion CH1 may further penetrate a portion of the source structure SS, and a lower end of the first channel portion CH1 may be positioned in the plate layer 101.

Each of the channel structures CH may include a channel layer 140, a gate dielectric layer 145, a channel filling insulating layer 147, and a channel pad 149 disposed in a channel hole. The channel layer 140, the gate dielectric layer 145, and the channel filling insulating layer 147 may be connected to each other between the first, second, and third channel portions CH1, CH2, and CH3.

The channel layer 140 may be formed in an annular shape surrounding the channel filling insulating layer 147 therein, but in example implementations, the channel layer 140 may also have a columnar shape such as a cylindrical shape or a prism shape without the channel filling insulating layer 147. The channel layer 140 may be connected to the first horizontal conductive layer 102 in a lower portion. The channel layer 140 may include a semiconductor material such as polycrystalline silicon or single crystal silicon.

The gate dielectric layer 145 may be disposed between the gate electrodes 130 and the channel layer 140. Although not specifically illustrated, the gate dielectric layer 145 may include a tunneling layer, a charge storage layer, and a blocking layer stacked in order from the channel layer 140. The tunneling layer may tunnel electric charge into the charge storage layer and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include, for example, silicon oxide (SiO₂), silicon nitride (Si₃N₄), silicon oxynitride (SiON), a high-k dielectric material, or a combination thereof. In example implementations, at least a portion of the gate dielectric layer 145 may extend in the horizontal direction along the gate electrodes 130.

The channel pad 149 may be disposed only on an upper end of the third channel portion CH3 in an upper portion. The channel pad 149 may include, for example, doped polycrystalline silicon.

The isolation regions MS may penetrate at least a portion of the gate electrodes 130 and may extend in the first direction (X-direction). As illustrated in FIG. 1A, the isolation regions MS may be disposed in parallel with each other. A portion of the isolation regions MS may extend along the first region R1 and the second region R2 as an integrated region, and the other portion may extend only to a portion of the second region R2, or may be disposed intermittently in the first region R1 and the second region R2. However, in example implementations, the arrangement, number, or the like, of the isolation regions MS are not limited to the example illustrated in FIG. 1A.

The isolation regions MS may penetrate the gate electrodes 130 stacked on the plate layer 101, may further penetrate the first and second horizontal conductive layers 102 and 104 therebelow and may be connected to the plate layer 101. The isolation regions MS may have a shape of which a width decreases toward the plate layer 101 due to a high aspect ratio. For example, a side surface of the isolation regions MS may have a substantially constant slope such that a width may decrease continuously or consecutively, and may not have a bent portion on the side surface.

In the isolation regions MS, the first isolation insulating layer 105 may be disposed. The first isolation insulating layer 105 may include, for example, silicon oxide, silicon nitride, or silicon oxynitride.

Referring to FIGS. 1A and 1D, the auxiliary isolation regions US may extend in the first direction (X-direction) between adjacent isolation regions MS. The auxiliary isolation regions US may be disposed in a portion of the second region R2 and the first region R1. The auxiliary isolation regions US may penetrate a portion of the gate electrodes 130, including the upper gate electrode 130U of the uppermost portion of the gate electrodes 130. The auxiliary isolation regions US may isolate, for example, three gate electrodes 130 from each other in the second direction (Y-direction). However, the number of gate electrodes 130 isolated by the auxiliary isolation regions US may be varied in example implementations.

In the auxiliary isolation region US, a second isolation insulating layer 103 may be disposed. The second isolation insulating layer 103 may include, for example, silicon oxide, silicon nitride, or silicon oxynitride.

The contact plugs 170 may be connected to gate pad regions GP of the gate electrodes 130 in the second region R2. The contact plugs 170 may penetrate at least a portion of the cell region insulating layers 192, 194, and 196, and may be connected to each of the gate pad regions GP of the gate electrodes 130 of which upper surfaces are exposed. The contact plugs 170 may penetrate the gate electrodes 130 above and below the gate pad regions GP, and may penetrate the second horizontal conductive layer 104, the horizontal insulating layer 110, and the plate layer 101 and may be connected to circuit interconnection lines 280 in the peripheral circuit region PERI. The contact plugs 170 may be spaced apart from the gate electrodes 130 above and below the gate pad regions GP by the contact insulating structures 160. The contact plugs 170 may be spaced apart from the plate layer 101, the horizontal insulating layer 110, and the second horizontal conductive layer 104 by the substrate insulating layers 121.

The contact plugs 170 may have a shape corresponding to the channel structures CH. Each of the contact plugs 170 may include first to third contact portions MC1, MC2, and MC3 stacked from a lower portion. The first, second, and third contact portions MC1, MC2, and MC3 may penetrate the first, second, and third stack structures GS1, GS2, and GS3 of the gate structure GS, respectively. The first contact portion MC1 may further penetrate the substrate insulating layer 121. The first to third contact portions MC1, MC2, and MC3 may have a cylindrical shape of which a width decreases toward the substrate 201 due to an aspect ratio. Each of the first to third contact portions MC1, MC2, and MC3 may have a substantially constant slope. The first contact portion MC1 may further include a landing region of which a width is enlarged below the substrate insulating layer 121. However, in some example implementations, the first contact portion MC1 may not include the landing region.

The first, second, and third contact portions MC1, MC2, and MC3 may have a shape in which a width of an upper surface of the contact portion disposed in a lower portion is greater than a width of a lower surface of the contact portion disposed in an upper portion in an interconnected region or on an interfacial surface. Accordingly, similarly to the channel structure CH, the contact plug 170 may have bent portions due to a difference in widths at interfacial surfaces between the first, second, and third contact portions MC1, MC2, and MC3.

A level of an interfacial surface between the first contact portion MC1 and the second contact portion MC2 may be the same as a level of an interfacial surface between the first channel portion CH1 and the second channel portion CH2. In an example, a level of an upper surface of the first contact portion MC1 may be the same as a level of an upper surface of the first channel portion CH1, and a level of an upper surface of the second contact portion MC2 may be the same as a level of an upper surface of the second channel portion CH2.

The contact plugs 170 may include a conductive material, for example, at least one of tungsten (W), copper (Cu), aluminum (Al), and alloys thereof. In some example implementations, the contact plugs 170 may include a barrier layer extending along a side surface and a bottom surface, or may have an air gap therein.

The contact insulating structures 160 may be disposed to surround a side surface of each of the contact plugs 170 above and below the gate pad region GP. In some implementations, the contact insulating structures 160 may be disposed above a corresponding gate pad region GP. In some implementations, the contact insulating structures 160 may be disposed above and below a corresponding gate pad region GP. In some implementations, the contact insulating structures 160 may be disposed below a corresponding gate pad region GP. In the present disclose, the contact insulating structures 160 that are disposed above and/or below the corresponding gate pad region GP can also be described as being disposed at the corresponding gate pad region GP. The contact insulating structures 160 may be spaced apart from each other in the third direction (Z-direction) around each of the contact plugs 170. The contact insulating structures 160 may extend horizontally from a side surface of each of the contact plugs 170. The contact insulating structures 160 may be disposed at substantially the same level as the gate electrodes 130, respectively. The contact insulating structures 160 may include an insulating material, for example, silicon oxide, silicon nitride, or silicon oxynitride.

The contact insulating structures 160 may include a first contact insulating structure 160a and a second contact insulating structure 160b distinct from the first contact insulating structure 160a. In an example, the first contact insulating structure 160a may surround the first contact plug 170a. The second contact insulating structure 160b may surround the second contact plug 170b and the second dummy vertical structure 175b.

The contact plugs 170 may include the first contact plug 170a and the second contact plug 170b. The first contact plug 170a may be a contact plug surrounded by the first contact insulating structure 160a, and the second contact plug 170b may be a contact plug surrounded by the second contact insulating structure 160b.

Referring to FIGS. 1A, 1B, and 1C, the dummy vertical structures 175 may be spaced apart from each other in rows and columns in the second region R2. The dummy vertical structures 175 may be disposed to surround each of the contact plugs 170. For example, as illustrated in FIG. 1A, when viewed on a plane, four dummy vertical structures 175 may surround the contact plugs 170, respectively. In an example, at least one of the four dummy vertical structures 175 may share a second contact plug 170b and a second contact insulating structure 160b.

As illustrated in FIG. 1C, the dummy vertical structures 175 may be regularly arranged in regions in which the contact plugs 170 are spaced apart from each other in the first direction (X-direction). However, in example implementations, the arrangement shape of the dummy vertical structures 175 may be varied. When viewed on a plane, the dummy vertical structures 175 may have a circular shape, oval shape, or a shape similar thereto.

The dummy vertical structures 175 may have a shape corresponding to the contact plugs 170. Each of the dummy vertical structures 175 may include first to third dummy extension portions IC1, IC2, and IC3 stacked from a lower portion. The first to third dummy extension portions IC1, IC2, and IC3 may penetrate the gate structure GS. A lower surface of the first dummy extension portion IC1 may be buried in the plate layer 101. The first to third dummy extension portions IC1, IC2, and IC3 may have a cylindrical shape of which a width decreases toward the plate layer 101 due to an aspect ratio.

The first to third dummy extension portions IC1, IC2, and IC3 may have a shape of which a width of an upper surface of the dummy extension portion disposed in the lower portion is greater than a width of a lower surface of the dummy extension portion disposed in an upper portion in a connected region or on an interfacial surface. Accordingly, similarly to the contact plug 170, the dummy vertical structures 175 may also have bent portions due to a difference in widths at an interfacial surface between the first to third dummy extension portions IC1, IC2, and IC3.

The dummy vertical structures 175 may have a structure the same as or different from the channel structures CH. When the dummy vertical structures 175 are formed together with the channel structures CH, the dummy vertical structures 175 may have the same structure as the channel structures CH. A diameter or a maximum width of the dummy vertical structures 175 may be greater than a diameter of the channel structures CH, but an example implementation thereof is not limited thereto.

When the dummy vertical structures 175 are formed using a portion during in process of forming the contact plugs 170, the dummy vertical structures 175 may have a structure different from the channel structures CH. The dummy vertical structures 175 do not include a conductive layer and may include an insulating material. For example, dummy vertical structures 175 may include silicon oxide, silicon nitride, or silicon oxynitride.

The dummy vertical structures 175 may not be electrically connected to interconnection structures in an upper portion, and may not form a memory cell string, differently from the channel structures in the semiconductor device 100.

The dummy vertical structures 175 may include first dummy vertical structures 175a and second dummy vertical structures 175b. The dummy vertical structure disposed adjacent to the first contact plug 170a among the dummy vertical structures 175 and surrounded by the dummy insulating structures 150 may be the “first dummy vertical structure 175a,” and the dummy vertical structure disposed adjacent to the second contact plug 170b among the dummy vertical structures 175 and sharing the second contact plug 170b and the second contact insulating structure 160b may be the “second dummy vertical structure 175b.”

The dummy insulating structures 150 may be spaced apart from each other in the third direction (Z-direction) around each of the first dummy vertical structures 175a. The dummy insulating structures 150 may be disposed alternately with the interlayer insulating layers 120 and disposed at substantially the same level as each of the gate electrodes 130. Each of the dummy insulating structures 150 may be disposed at the same level as the first and second contact insulating structures 160a and 160b.

The studs 180 may form a cell interconnection structure electrically connected to memory cells in the memory cell region CELL. The studs 180 may be connected to the channel structures CH and the contact plugs 170 and may be electrically connected to the channel structures CH and the gate electrodes 130. The studs 180 may have a form of plugs, but an example implementation thereof is not limited thereto, and may also have a line form. In example implementations, the number of plugs and interconnection lines included in the cell interconnection structure may be varied. The studs 180 may include a metal, for example, tungsten (W), copper (Cu), aluminum (Al), or the like.

The first to third cell region insulating layers 192, 194, and 196 may be disposed to cover the first, second, and third stack structures GS1, GS2, and GS3, respectively. The first to third cell region insulating layers 192, 194, and 196 may be disposed in an uppermost portion of the first, second, and third stack structures GS1, GS2, and GS3. Each of the first, second, and third cell region insulating layers 192, 194, and 196 may be formed of an insulating material, and may be formed in a plurality of insulating layers. When the first, second, and third cell region insulating layers 192, 194, and 196 include the same material as that of the interlayer insulating layers 120, interfacial surfaces between the interlayer insulating layers 120 may not be distinct. The first, second, and third cell region insulating layers 192, 194, and 196 and the interlayer insulating layers 120 may be collectively referred to as interlayer insulating layers in example implementations.

In example implementations, the first direction (X-direction) and the second direction (Y-direction) may be perpendicular to each other. The first direction (X-direction) and the second direction (Y-direction) may be perpendicular to the third direction (Z-direction). The horizontal direction may indicate the first direction (X-direction) and the second direction (Y-direction), or a direction that is angled relative to the first direction or the second direction, and the vertical direction may indicate the third direction (Z-direction). The horizontal direction, the first direction and the second direction can be horizontal.

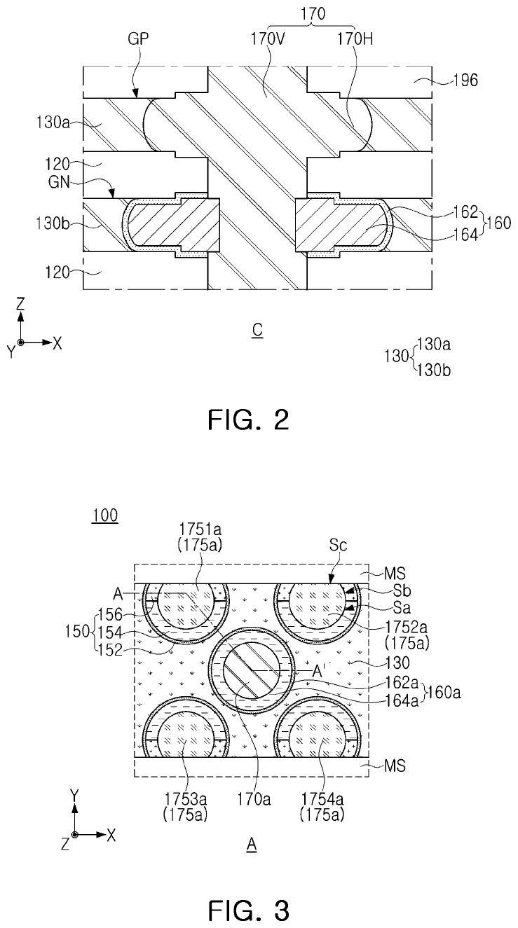

FIG. 2 is an enlarged diagram illustrating region C of the semiconductor device in FIG. 1B.

Referring to FIG. 2, the contact plugs 170 may be connected to the first gate electrode portion 130a of the gate electrodes 130 through the gate pad regions GP. The contact plug 170 described with reference to FIG. 2 may be also applied to the first and second contact plugs 170a and 170b in FIG. 1A, and the contact insulating structure 160 described with reference to FIG. 2 may also be applied to the first and second contact insulating structures 160a and 160b in FIG. 1B.

The contact plug 170 may have a form enlarged in the horizontal direction toward the first gate electrode portion 130a. In an example, the contact plugs 170 may include a vertical extension portion 170V penetrating the gate electrodes 130 and the interlayer insulating layers 120 and extending in the third direction (Z-direction), and a horizontal extension portion 170H enlarged in the horizontal direction from the vertical extension portion 170V and in contact with the gate pad region GP.

Each of the gate electrodes 130 may include a gate pad region GP and a gate stack region GN, which is a region other than the gate pad region GP. The gate pad region GP may be a region of the gate electrode layer not covered by other gate electrodes due to a step structure. The gate stack region GN may be another region of the gate electrode layer covered by other gate electrodes. The gate pad region GP may be in contact with the horizontal extension portion 170H of the contact plug 170.

Each of the gate electrodes 130 may include a first gate electrode portion 130a corresponding to the gate pad region GP and a second gate electrode portion 130b corresponding to the gate stack region GN. In example implementations, the first gate electrode portion 130a may be referred to as a gate contact pad, and the second gate electrode portion 130b may be referred to as a gate stack structure.

The contact insulating structures 160 may be disposed alternately with the interlayer insulating layers 120 and may be disposed at the same level as the second gate electrode portions 130b of the gate electrodes 130 in a lower portion of the gate pad region GP. The contact insulating structures 160 may be disposed between the gate stack region GN and the vertical extension portion 170V. The contact insulating structures 160 may overlap the horizontal extension portion 170H of the contact plug 170 in the third direction (Z-direction). The contact plug 170 may be electrically isolated from the second gate electrode portion 130b in a lower portion of the gate pad region GP by the contact insulating structure 160.

Each of the contact insulating structures 160 may include a contact insulating pattern 164 surrounding a side surface of the contact plugs 170 and a contact insulating liner 162 surrounding an external side surface of the contact insulating pattern 164. The contact insulating liner 162 may be in contact with the second gate electrode portion 130b of the gate electrode 130. The contact insulating pattern 164 may include a first insulating material, and the contact insulating liner 162 may include a second insulating material different from the first insulating material. For example, the contact insulating pattern 164 may include silicon nitride, and the contact insulating liner 162 may include silicon oxide.

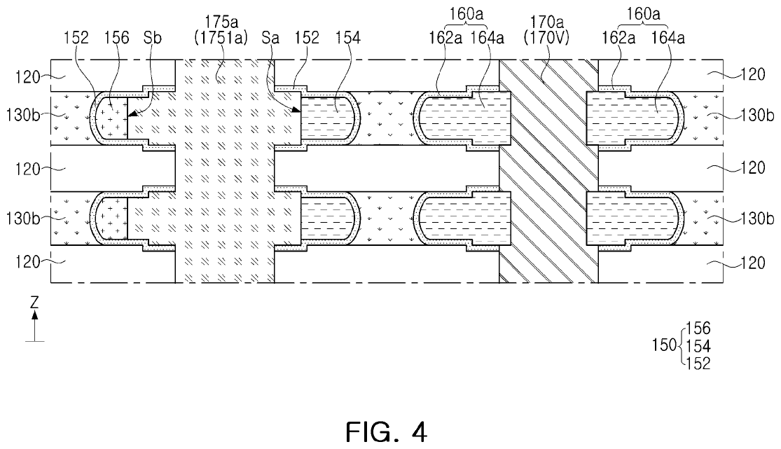

FIG. 3 is an enlarged diagram illustrating region A of the semiconductor device in FIG. 1A. FIG. 4 is a cross-sectional diagram illustrating a semiconductor device taken along line A-A′ in FIG. 3 according to an example implementation. FIG. 3 is a plan diagram illustrating the first contact plug 170a, the first contact insulating structure 160a, the first dummy vertical structure 175a, and the dummy insulating structures 150 disposed at the same level as the second gate electrode portions 130b in FIG. 2.

Referring to FIGS. 3 and 4, region A of the semiconductor device 100 may include a first contact plug 170a disposed between the isolation regions MS, first dummy vertical structures 175a adjacent to the first contact plug 170a, first contact insulating structures 160a surrounding the first contact plug 170a and spaced apart from each other in the third direction (Z-direction) in a lower portion of the gate contact region (e.g., the gate pad region GP of FIG. 1B), and dummy insulating structures 150 surrounding the first dummy vertical structures 175a, respectively, and spaced apart from each other in the third direction (Z-direction).

The isolation regions MS may extend in the first direction (X-direction) and may be spaced apart from each other in the second direction (Y-direction). For example, the isolation regions MS may include a first isolation region extending in a first direction (X-direction) and a second isolation region spaced apart from the first isolation region in the second direction (Y-direction). The first contact plug 170a may be disposed between the first isolation region and the second isolation region.

The first contact insulating structures 160a may surround the vertical extension portion of the first contact plug 170a (e.g., the vertical extension portion 170V of FIG. 2) and may be spaced apart from each other in a third direction (Z-direction). The first contact insulating structures 160a may be disposed alternately with the interlayer insulating layers 120 in the third direction (Z-direction). Each of the first contact insulating structures 160a may include a 1-1 contact insulating pattern 164a surrounding a vertical extension portion 170V of the first contact plug 170a and a first contact insulating liner 162a surrounding the 1-1 contact insulating pattern 164a. In an example, the 1-1 contact insulating pattern 164a may include a first insulating material, and the first contact insulating liner 162a may include a second insulating material different from the first insulating material. For example, the 1-1 contact insulating pattern 164a may include silicon nitride, and the first contact insulating liner 162a may include at least one of silicon oxide, silicon carbide, or silicon oxynitride.

The first dummy vertical structures 175a may be disposed adjacent to the first contact plug 170a and may surround the first contact plug 170a. The first dummy vertical structures 175a may include four dummy structures surrounding the first contact plug 170a. In an example, the first dummy vertical structures 175a may include a 1-1 dummy vertical structure 1751a, a 1-2 dummy vertical structure 1752a, a 1-3 dummy vertical structure 1753a and a 1-4 dummy vertical structure 1754a. In an example, when viewed on the plane, the 1-1 dummy vertical structure 1751a may be disposed on the left side on the first contact plug 170a, the 1-2 dummy vertical structure 1752a may be disposed on the right side on the first contact plug 170a, the 1-3 dummy vertical structure 1753a may be disposed on the left side below the first contact plug 170a, and the 1-4 dummy vertical structure 1754a may be disposed on the right side below the first contact plug 170a. In an example, the 1-1 dummy vertical structure 1751a and the 1-2 dummy vertical structure 1752a may be in contact with a first isolation region disposed on the first contact plug 170a among the isolation regions MS when viewed on a plane, and the 1-3 dummy vertical structure 1753a and the 1-4 dummy vertical structure 1754a may be in contact with a second isolation region disposed below the first contact plug 170a among the isolation regions MS when viewed on a plane.

Each of the first dummy vertical structures 175a may include a first portion Sa adjacent to the first contact plug 170a, second portions Sb extending from the first portion Sa and connected by the first portion Sa, and a third portion Sc connecting the second portions Sb to each other and in contact with the isolation region MS. The first portion Sa of the first dummy vertical structures 175a may be more adjacent to the first contact plug 170a than the second portions Sb of the first dummy vertical structures 175a. The third portion Sc of each of the first dummy vertical structures 175a may be a side surface exposed by the gate electrodes 130.

When viewed on a plane, a spacing distance between the first contact plug 170a and the first dummy vertical structures 175a may be the same. For example, when viewed on a plane, the distance between the first contact plug 170a and the 1-1 dummy vertical structure 1751a, a distance between the first contact plug 170a and the 1-2 dummy vertical structure 1752a, a distance between the first contact plug 170a and the 1-3 dummy vertical structure 1753a, and a distance between the first contact plug 170a and the 1-4 dummy vertical structure 1754a may be the same. However, an example implementation thereof is not limited thereto. For example, a spacing distance between the first contact plug 170a and the first dummy vertical structures 175a may be different.

Each of the first dummy vertical structures 175a may be surrounded by dummy insulating structures 150. In an example, the dummy insulating structures 150 may surround the 1-1 dummy vertical structure 1751a, the 1-2 dummy vertical structure 1752a, the 1-3 dummy vertical structure 1753a and the 1-4 dummy vertical structure 1754a, respectively, and may be spaced apart from each other in the third direction (Z-direction). For example, the dummy insulating structures 150 may be disposed alternately with the interlayer insulating layers 120 and may surround the 1-1 dummy vertical structure 1751a. In an example, the dummy insulating structures 150 may be disposed at the same level as the gate electrodes 130 and the first contact insulating structures 160a.

The dummy insulating structures 150 surrounding the 1-1 dummy vertical structure 1751a may be spaced apart from each other in the third direction (Z-direction) and may be spaced apart from the dummy insulating structures 150 surrounding the 1-2 dummy vertical structure 1752a in the horizontal direction. The dummy insulating structures 150 may be spaced apart from the first contact insulating structures 160a in the horizontal direction. In an example, the gate electrode 130 may be disposed between the dummy insulating structures 150 and the first contact insulating structure 160a when viewed on a plane

The dummy insulating structure 150 may include a first dummy insulating pattern 154 surrounding a first portion Sa of each of the first dummy vertical structures 175a, a second dummy insulating patterns 156 surrounding a second portions Sb of each of the first dummy vertical structures 175a, and a dummy insulating liner 152 surrounding the first dummy insulating pattern 154 and the second dummy insulating patterns 156. For example, a dummy insulating structure 150 surrounding a 1-1 dummy vertical structure 1751a may include a first dummy insulating pattern 154 in contact with a first portion Sa of the 1-1 dummy vertical structure 1751a, second dummy insulating patterns 156 in contact with the second portions Sb of the 1-1 dummy vertical structure 1751a, and a dummy insulating liner 152 surrounding the first dummy insulating pattern 154 and the second dummy insulating patterns 156. The first dummy insulating pattern 154 may correspond to a surface profile of the first portion Sa, and the second dummy insulating patterns 156 may correspond to a surface profile of the second portions Sb. The second dummy insulating patterns 156 may be disposed between the first dummy insulating pattern 154 and the isolation region MS when viewed on a plane. In an example, the first dummy insulating pattern 154 may be disposed more adjacent to the first contact plug 170a than the second dummy insulating patterns 156. When viewed on a plane, the second dummy insulating patterns 156 of each of the 1-1 dummy vertical structure 1751a and the 1-2 dummy vertical structure 1752a may be disposed between the first dummy insulating pattern 154 of each of the 1-1 dummy vertical structure 1751a and the 1-2 dummy vertical structure 1752a and the first isolation region disposed on an upper side of the first contact plug 170a among the isolation regions MS. When viewed on a plane, the second dummy insulating patterns 156 of each of the 1-3 dummy vertical structure 1753a and the 1-4 dummy vertical structure 1754a may be disposed between the first dummy insulating pattern 154 of each of the 1-3 dummy vertical structure 1753a and the 1-4 dummy vertical structure 1754a and the second isolation region disposed on a lower side of the first contact plug 170a among the isolation regions MS.

The first dummy insulating pattern 154 of the 1-1 dummy vertical structure 1751a may be disposed parallel to the first dummy insulating pattern 154 of the 1-2 dummy vertical structure 1752a in the first direction (X-direction). The second dummy insulating patterns 156 of the 1-1 dummy vertical structure 1751a may be disposed side by side with the second dummy insulating patterns 156 of the 1-2 dummy vertical structure 1752a in the first direction (X-direction). The first dummy insulating pattern 154 of the 1-3 dummy vertical structure 1753a may be disposed side by side with the first dummy insulating pattern 154 of the 1-4 dummy vertical structure 1754a in the first direction (X-direction). The second dummy insulating patterns 156 of the 1-3 dummy vertical structure 1753a may be disposed side by side with the second dummy insulating patterns 156 of the 1-4 dummy vertical structure 1754a in the first direction (X-direction)

The first dummy insulating pattern 154 may include a first insulating material, and the second dummy insulating pattern 156 may include a second insulating material different from the first insulating material. For example, the first dummy insulating pattern 154 may include silicon nitride, and the second dummy insulating pattern 156 may include silicon oxide.

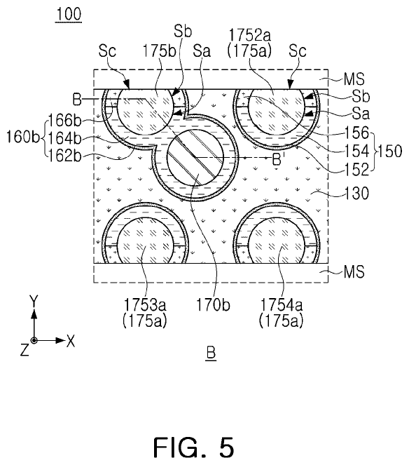

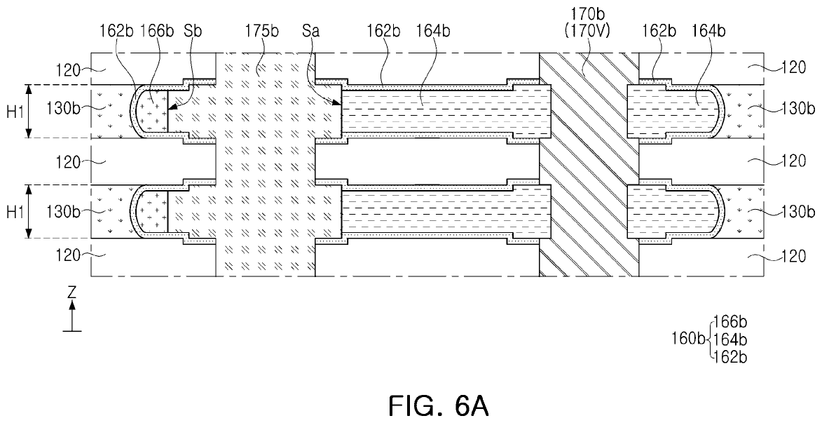

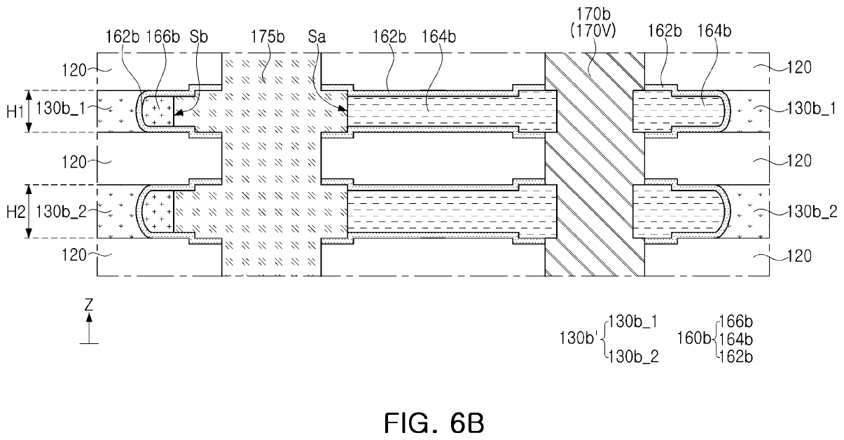

FIG. 5 is an enlarged diagram illustrating region B of the semiconductor device in FIG. 1A. FIG. 6A is a cross-sectional diagram illustrating a semiconductor device taken along line B-B′ in FIG. 5 according to an example implementation. FIG. 6B is a cross-sectional diagram illustrating a semiconductor device taken along line B-B′ in FIG. 5 according to another example implementation. FIG. 5 is a plan diagram illustrating the second contact plug 170b, the first and second dummy vertical structures 175a and 175b, the dummy insulating structure 150, and the second contact insulating structure 160b disposed at the same level as the second gate electrode portions 130b in FIG. 2.

Referring to FIGS. 5 and 6A, region B of the semiconductor device 100 may include a second contact plug 170b disposed between the isolation regions MS, first and second dummy vertical structures 175a and 175b adjacent to the second contact plug 170b, second contact insulating structures 160b surrounding the second contact plug 170b and the second dummy vertical structure 175b and spaced apart from each other in the third direction (Z-direction) in a lower portion of the gate contact region GP of the second contact plug 170b (e.g., the gate pad region GP of FIG. 1B), and dummy insulating structures 150 surrounding each of the first dummy vertical structures 175a and spaced apart from each other in the third direction (Z-direction).

The second contact plug 170b may be disposed between the isolation regions MS. The first dummy vertical structures 175a and the second dummy vertical structures 175b may be disposed adjacent to the second contact plug 170b and may surround the second contact plug 170b. In an example, one second dummy vertical structure 175b and three first dummy vertical structures 175a may surround the second contact plug 170b. For example, the second dummy vertical structure 175b, the 1-2 dummy vertical structure 1752a, the 1-3 dummy vertical structure 1753a, and the 1-4 dummy vertical structure 1754a may surround the second contact plug 170b. The second dummy vertical structure 175b may be disposed on the left side on the second contact plug 170b, the 1-2 dummy vertical structure 1752a may be disposed on the right side on the second contact plug 170b, the 1-3 dummy vertical structure 1753a may be disposed on the left side below the second contact plug 170b, and the 1-4 dummy vertical structure 1754a may be disposed on the right side below the second contact plug 170b. However, an example implementation thereof is not limited thereto, and the second dummy vertical structure 175b may be disposed on the right side on the second contact plug 170b, or may be disposed on the left side or the right side below the second contact plug 170b.

The second dummy vertical structure 175b and the 1-2 dummy vertical structure 1752a may be in contact with the first isolation region MS disposed on an upper side of the second contact plug 170b among the isolation regions MS when viewed on a plane, and the 1-3 dummy vertical structure 1753a and the 1-4 dummy vertical structure 1754a may be in contact with the second isolation region disposed on a lower side of the second contact plug 170b among the isolation regions MS when viewed on a plane.

The second dummy vertical structure 175b may include a first portion Sa adjacent to the second contact plug 170b, second portions Sb extending from the first portion Sa and connected by the first portion Sa, and a third portion Sc connecting the second portions Sb and in contact with the isolation region MS. In an example, the first portion Sa of the second dummy vertical structure 175b may be more adjacent to the second contact plug 170b than the second portions Sb of the second dummy vertical structure 175b.

The second contact plug 170b and the second dummy vertical structure 175b may share the second contact insulating structures 160b. Each of the second contact insulating structures 160b may be in contact with the vertical extension portion of the second contact plug 170b (e.g., the vertical extension portion 170V of FIG. 2) and the second dummy vertical structure 175b, and may be spaced apart from each other in the third direction (Z-direction). The second contact insulating structures 160b may be disposed alternately with the interlayer insulating layers 120 in the third direction (Z-direction). Each of the second contact insulating structures 160b may be in contact with the second contact plug 170b and the second dummy vertical structure 175b below the gate pad region GP.

Each of the second contact insulating structures 160b may include a 2-1 contact insulating pattern 164b in contact with the vertical extension portion 170V of the second contact plug 170b and the first portion Sa of the second dummy vertical structure 175b, 2-2 contact insulating patterns 166b extending from the 2-1 contact insulating pattern 164b and in contact with the second portions Sb of the second dummy vertical structure 175b, and a second contact insulating liner 162b surrounding the 2-1 contact insulating pattern 164b and the 2-2 contact insulating patterns 166b.

The 2-1 contact insulating pattern 164b may be disposed along a surface profile of an external side surface of the second contact plug 170b and an external side surface of the first portion Sa of the second dummy vertical structure 175b. The 2-2 contact insulating patterns 166b may be disposed along a surface profile of an external side surface of the second portions Sb of the second dummy vertical structure 175b. When viewed on a plane, the 2-2 contact insulating patterns 166b may be disposed between the 2-1 contact insulating pattern 164b and the isolation region MS.

The 2-1 contact insulating pattern 164b may include a first insulating material, the 2-2 contact insulating pattern 166b may include a second insulating material different from the first insulating material, and the second contact insulating liner 162b may include a third insulating material. For example, the 2-1 contact insulating pattern 164b may include silicon nitride, the 2-2 contact insulating pattern 166b may include silicon oxide, and the second contact insulating liner 162b may include at least one of silicon oxide, silicon carbide, or silicon oxynitride.

The 1-2 dummy vertical structure 1752a, the 1-3 dummy vertical structure 1753a, and the 1-4 dummy vertical structure 1754a may be surrounded by dummy insulating structures 150. The dummy insulating structure 150 disposed in region B of the semiconductor device 100 may correspond to the dummy insulating structure 150 disposed in region A of the semiconductor device 100.

The second contact insulating structures 160b may be spaced apart from the dummy insulating structures 150 in the horizontal direction. When viewed on a plane, the gate electrode 130 (e.g., the second gate electrode portion 130b in FIG. 2) may be disposed between the second contact insulating structure 160b and the dummy insulating structures 150.

In an example, when viewed on a plane, a spacing distance between the second contact plug 170b and the second dummy vertical structure 175b may be less than a spacing distance between the second contact plug 170b and each of the first dummy vertical structures 175a. For example, the spacing distance between the second contact plug 170b and the second dummy vertical structure 175b may be less than the spacing distance between the second contact plug 170b and the 1-2 dummy vertical structure 1752a.

Referring to FIG. 6A, each of the second gate electrode portions 130b may have a first height H1 in the third direction (Z-direction). To correspond to this, the second gate electrode portions 130b and the second contact insulating structures 160b disposed at the same level may have the same thickness in the third direction (Z-direction).

Referring to FIG. 6B, the second gate electrode portions 130b′ may include a 2-1 gate electrode portion 130b_1 having a first height H1 in the third direction (Z-direction) and a 2-2 gate electrode portion 130b_2 having a second height H2 greater than the first height H1.

Correspondingly, a thickness of the second contact insulating structure 160b disposed at the same level as the 2-1 gate electrode portion 130b_1 may be less than a thickness of the second contact insulating structure 160b disposed at the same level as the 2-2 gate electrode portion 130b_2.

In example implementations, a semiconductor device 100 may include first and second contact plugs 170a and 170b, first dummy vertical structures 175a surrounding the first contact plug 170a, a second dummy vertical structure 175b adjacent to the second contact plug 170b, first contact insulating structures 160a surrounding the first contact plug 170a, a second contact insulating structure 160b in contact with the second contact plug 170b and the second dummy vertical structure 175b, and a dummy insulating structure 150 surrounding the first dummy vertical structures 175a. However, an example implementation thereof is not limited thereto. For example, the semiconductor device 100 may include first contact plugs 170a, first dummy vertical structures 175a, first contact insulating structures 160a surrounding the first contact plugs 170a, and dummy insulating structures 150 surrounding the first dummy vertical structures 175a, other than the second contact plugs 170b illustrated in FIGS. 1A and 5.

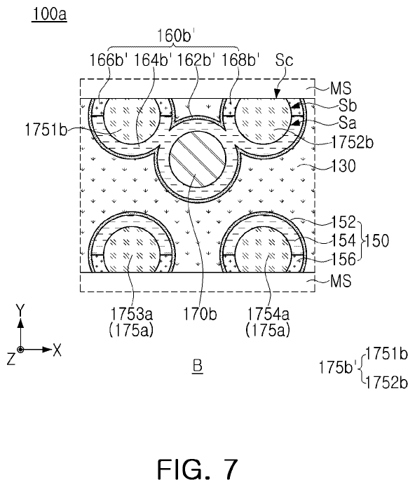

FIG. 7 is an enlarged diagram illustrating region B of the semiconductor device in FIG. 1A according to another example implementation.

Other than the second dummy vertical structures 175b′ and the second contact insulating structures 160b′ in contact with the second dummy vertical structures 175b′ and the second contact plug 170b illustrated in FIG. 7, overlapping descriptions of the components the same as or corresponding to the components illustrated in FIG. 5 will not be provided.

Referring to FIG. 7, region B of the semiconductor device 100a may include a second contact plug 170b disposed between the isolation regions MS, first and second dummy vertical structures 175a and 175b′ adjacent to the second contact plug 170b, second contact insulating structures 160b′ surrounding the second contact plug 170b and the second dummy vertical structures 175b′ and spaced apart from each other in the third direction (Z-direction) in a lower portion of the gate contact region (e.g., the gate pad region GP in FIG. 1B) of the second contact plug 170b, and dummy insulating structures 150 surrounding the first dummy vertical structures 175a, respectively, and spaced apart from each other in the third direction (Z-direction).

The first dummy vertical structures 175a and the second dummy vertical structures 175b′ may be disposed adjacent to the second contact plug 170b and may surround the second contact plug 170b. In an example, two second dummy vertical structures 175b′ and two first dummy vertical structures 175a may surround the second contact plug 170b. The second dummy vertical structures 175b′ may include a 2-1 dummy vertical structure 1751b and a 2-2 dummy vertical structure 1752b spaced apart from the 2-1 dummy vertical structure 1751b in the horizontal direction. For example, the 2-1 dummy vertical structure 1751b and the 2-2 dummy vertical structure 1752b may be spaced apart from each other in the first horizontal direction (X-direction).

The 2-1 dummy vertical structure 1751b, the 2-2 dummy vertical structure 1752b, the 1-3 dummy vertical structure 1753a, and the 1-4 dummy vertical structure 1754a may surround the second contact plug 170b. The 2-1 dummy vertical structure 1751b may be disposed on the left side on the second contact plug 170b, the 2-2 dummy vertical structure 1752b may be disposed on the right side on the second contact plug 170b, the 1-3 dummy vertical structure 1753a may be disposed on the left side below the second contact plug 170b, and the 1-4 dummy vertical structure 1754a may be disposed on the right side below the second contact plug 170b. However, an example implementation thereof is not limited thereto. For example, the 2-1 dummy vertical structure 1751b may be disposed on the right side on the second contact plug 170b, and the 2-2 dummy vertical structure 1752b may be disposed on the right side below the second dummy plug 170b. In this case, the 1-3 dummy vertical structure 1753a may be disposed on the left side on the second contact plug 170b, and the 1-4 dummy vertical structure 1754a may be disposed on the left side below the second contact plug 170b.

The 2-1 dummy vertical structure 1751b and the 2-2 dummy vertical structure 1752b may be in contact with the first isolation region disposed on an upper side of the second contact plug 170b among the isolation regions MS when viewed on a plane, and the 1-3 dummy vertical structure 1753a and the 1-4 dummy vertical structure 1754a may be in contact with the second isolation region disposed on a lower side of the first contact plug 170a among the isolation regions MS when viewed on a plane.

The 2-1 dummy vertical structure 1751b and the 2-2 dummy vertical structure 1752b may include a first portion Sa adjacent to the second contact plug 170b, second portions Sb extending from the first portion Sa and connected by the first portion Sa, and a third portion Sc connecting the second portions Sb to each other and in contact with the isolation region MS. In an example, the first portions Sa of the second dummy vertical structures 175b′ may be more adjacent to the second contact plug 170b than the second portions Sb of the second dummy vertical structures 175b′.

The second contact insulating structures 160b′ may be disposed alternately with the interlayer insulating layers (e.g., the interlayer insulating layers 120 in FIG. 1B) and in contact with the vertical extension portions (e.g., the vertical extension portion 170V in FIG. 2) of the second contact plug 170b and the second dummy vertical structures 175b′, and may be spaced apart from each other in the third direction (Z-direction). The second contact insulating structure 160b′ may be in contact with the second contact plug 170b, the 2-1 dummy vertical structure 1751b, and the 2-2 dummy vertical structure 1752b. The second contact plug 170b, the 2-1 dummy vertical structure 1751b, and the 2-2 dummy vertical structure 1752b may share the second contact insulating structures 160b′.

Each of the second contact insulating structures 160b′ may include a 2-1 contact insulating pattern 164b′ in contact with a vertical extension portion (e.g., vertical extension portion 170V in FIG. 2) of the second contact plug 170b, a first portion Sa of the 2-1 dummy vertical structure 1751b, and in contact with the first portion Sa of the 2-2 dummy vertical structure 1752b, a 2-2 contact insulating pattern 166b′ in contact with the second portions Sb of the 2-1 dummy vertical structure 1751b, a 2-3 contact insulating pattern 168b′ in contact with the second portions Sb of the 2-2 dummy vertical structure 1752b, and a second contact insulating liner 162b′ surrounding the 2-1 contact insulating pattern 164b′, the 2-2 contact insulating pattern 166b′, and the 2-3 contact insulating pattern 168b′.

The 2-1 contact insulating pattern 164b′ may be disposed along surface profiles of an external side surface of the second contact plug 170b, an external side surface of the first portion Sa of the 2-1 dummy vertical structure 1751b, and an external side surface of the first portion Sa of the 2-2 dummy vertical structure 1752b. The 2-2 contact insulating patterns 166b′ may extend from a side surface of the 2-1 contact insulating pattern 164b′ and may be disposed along a surface profile of an external side surface of the second portions Sb of the 2-1 dummy vertical structure 1751b. The 2-3 contact insulating patterns 168b′ may extend from a side surface of the 2-1 contact insulating pattern 164b′ and may be disposed along a surface profile of an external side surface of the second portions Sb of the 2-2 dummy vertical structure 1752b. The 2-2 contact insulating patterns 166b′ and the 2-3 contact insulating patterns 168b′ may be disposed between the 2-1 contact insulating pattern 164b′ and the isolation region MS. The 2-2 contact insulating patterns 166b′ and the 2-3 contact insulating patterns 168b′ may be spaced apart from each other in the first direction (X-direction).

The 2-1 contact insulating pattern 164b′ may include the first insulating material, and the 2-2 contact insulating patterns 166b′ and the 2-3 contact insulating patterns 168b′ may include a second insulating material different from the first insulating material. The second contact insulating liner 162b′ may include a third insulating material. For example, the 2-1 contact insulating pattern 164b′ may include silicon nitride, the 2-2 contact insulating patterns 166b′ and the 2-3 contact insulating patterns 168b′ may include silicon oxide, and the second contact insulating liner 162b′ may include at least one of silicon oxide, silicon carbide, or silicon oxynitride.

Each of the 1-3 dummy vertical structure 1753a and the 1-4 dummy vertical structure 1754a may be surrounded by the dummy insulating structures 150. The dummy insulating structure 150 disposed in region B of the semiconductor device 100a may correspond to the dummy insulating structure 150 disposed in region B of the semiconductor device 100 in FIG. 5.

The second contact insulating structures 160b′ may be spaced apart from the dummy insulating structures 150 in the horizontal direction. When viewed on a plane, the gate electrode 130 (e.g., the second gate electrode portion 130b in FIG. 2) may be disposed between the second contact insulating structure 160b′ and the dummy insulating structures 150.

In an example, when viewed on a plane, a spacing distance between the second contact plug 170b and the 2-1 dummy vertical structure 1751b may be less than a spacing distance between the second contact plug 170b and the 1-3 dummy vertical structure 1753a (and the 1-4 dummy vertical structure 1754a).

In another example implementation, the second dummy vertical structures 175b′ may include the 2-1 dummy vertical structures 1751b and the 2-2 dummy vertical structures 1752b as illustrated, but the second dummy vertical structure 175b′ may include three dummy vertical structures. In this case, the second dummy vertical structures 175b′ may include the 2-1 dummy vertical structure, the 2-2 dummy vertical structure, and the 2-3 dummy vertical structure, and the 2-1 dummy vertical structure may be disposed on the upper left side of the second contact plug 170b, the 2-2 dummy vertical structure may be disposed on the upper right side of the second contact plug 170b, and the 2-3 dummy vertical structure may be disposed on the lower left side of the second contact plug 170b. Each of the second contact insulating structures 160b′ may be in contact with the second contact plug 170b and three 2-1 dummy vertical structures, 2-2 dummy vertical structures, and 2-3 dummy vertical structures included in the second dummy vertical structures 175b′.

In example implementations, a semiconductor device 100a may include first and second contact plugs 170a and 170b, first dummy vertical structures 175a surrounding the first contact plug 170a, a second dummy vertical structure 175b′ adjacent to the second contact plug 170b, first contact insulating structures 160a surrounding the first contact plug 170a, second contact insulating structures 160b′ in contact with the second contact plug 170b and the second dummy vertical structure 175b′, and a dummy insulating structure 150 surrounding the first dummy vertical structures 175a.

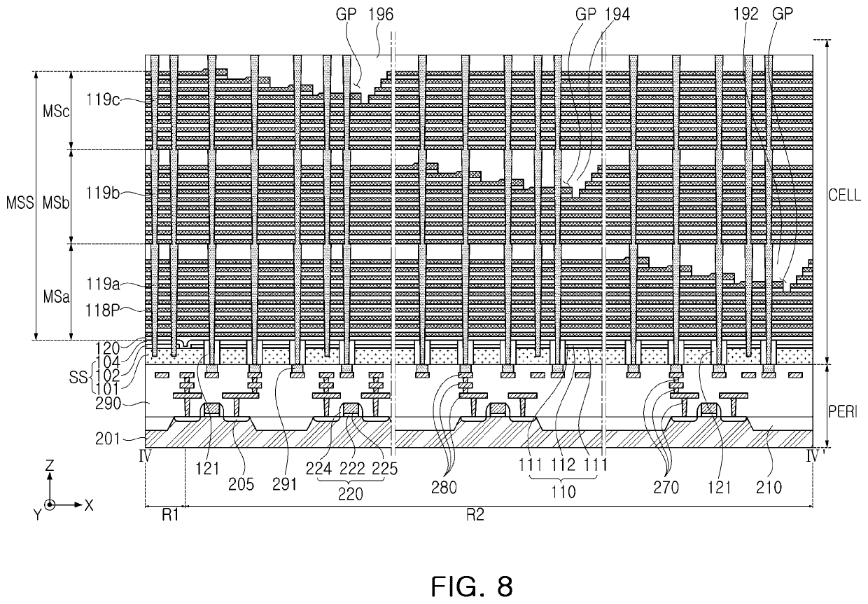

FIGS. 8 to 10 are cross-sectional diagrams illustrating a method of manufacturing a semiconductor device according to an example implementation. FIGS. 8 to 10 each illustrate cross-sections along line IV-IV′ of the semiconductor device in FIG. 1A.

Referring to FIG. 8, circuit devices 220, a circuit interconnection structure, and a peripheral region insulating layer 290 included in the peripheral circuit region PERI may be formed on the substrate 201.

The device isolation layers 210 may be formed in the substrate 201, and a circuit gate dielectric layer 222 and a circuit gate electrode 225 may be formed in order on the substrate 201. The device isolation layers 210 may be formed, for example, by a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but an example implementation thereof is not limited thereto. Thereafter, a spacer layer 224 may be formed on both sidewalls of the circuit gate dielectric layer 222 and the circuit gate electrode 225, and impurity regions 205 may be formed in the substrate 201 on both sides of the circuit gate dielectric layer 222 and the circuit gate electrode 225. In example implementations, the spacer layer 224 may be formed in a plurality of layers. The impurity regions 205 may be formed by performing an ion implantation process.

Among the circuit interconnection structures, the circuit contact plugs 270 may be formed by partially forming a peripheral region insulating layer 290, removing a portion thereof by etching, and filling the conductive material. The circuit interconnection lines 280 may be formed, for example, by depositing a conductive material and patterning the conductive material.

The peripheral region insulating layer 290 may be formed in a plurality of insulating layers. A respective portion of the peripheral region insulating layer 290 may be formed in each of processes for forming the circuit interconnection structure. Accordingly, a peripheral circuit region PERI may be formed.

On the peripheral circuit region PERI, a plate layer 101, a horizontal insulating layer 110, a second horizontal conductive layer 104, and a substrate insulating layer 121, in which a memory cell region CELL is provided, may be formed, and mold structure MSS and first to third vertical sacrificial layers 119a, 119b, and 119c may be formed.

The plate layer 101 may be formed on the peripheral region insulating layer 290. The plate layer 101 may be formed of, for example, polycrystalline silicon and may be formed by a CVD process. The polycrystalline silicon included in the plate layer 101 may include impurities.

When the plate layer 101 is formed, landing pads 291 may be formed together on the circuit interconnection lines 280 in an uppermost portion. The landing pads 291 may be formed in the region in which a lower end of the contact plugs 170 (see FIG. 1B) is disposed. First, before forming the plate layer 101, a portion of the peripheral region insulating layer 290 may be removed from the circuit interconnection lines 280 of the uppermost portion to form openings. When forming the plate layer 101, the openings may be filled with a material included in the plate layer 101, thereby forming the landing pads 291. The openings may be formed, for example, with a ground via for connecting the plate layer 101 to the circuit interconnection structure.

The first and second horizontal insulating layers 111 and 112 included in the horizontal insulating layer 110 may be alternately stacked on the plate layer 101. The horizontal insulating layer 110 may be layers in which a portion thereof is replaced with the first horizontal conductive layer 102 in FIG. 1B through a subsequent process. The first horizontal insulating layers 111 may include a material different from a material of the second horizontal insulating layer 112. For example, the first horizontal insulating layers 111 may be formed of the same material as the interlayer insulating layers 120, and the second horizontal insulating layer 112 may be formed of the same material as the subsequent sacrificial insulating layers 118P. Partial regions of the horizontal insulating layer 110, for example, a portion of the second region R2, may be removed by a pattern process.

The second horizontal conductive layer 104 may be formed on the horizontal insulating layer 110, and may be in contact with the plate layer 101 in the region from which the horizontal insulating layer 110 is removed.

The substrate insulating layer 121 may be formed to penetrate the plate layer 101 in partial regions including the region in which the contact plugs 170 are disposed. The substrate insulating layer 121 may be formed by removing a portion of the plate layer 101, the horizontal insulating layer 110 and the second horizontal conductive layer 104, and filling an insulating material. After filling the insulating material, a planarization process may be further performed using a chemical mechanical polishing (CMP) process. Accordingly, an upper surface of the substrate insulating layer 121 may be substantially coplanar with an upper surface of the second horizontal conductive layer 104.

Thereafter, the first mold structure MSa may be formed by alternately stacking sacrificial insulating layers 118P and interlayer insulating layers 120 on the second horizontal conductive layer 104 and the substrate insulating layer 121 at a height at which the first stack structure GS1 (see FIG. 1B) is disposed.

The sacrificial insulating layers 118P may be layers in which at least a portion is replaced by gate electrodes 130 (see FIG. 1B) through a subsequent process. The sacrificial insulating layers 118P may be formed of a material different from that of the interlayer insulating layers 120, and may be formed of a material etched with etch selectivity with respect to the interlayer insulating layers 120 under specific etch conditions. For example, the interlayer insulating layer 120 may be formed of at least one of silicon oxide and silicon nitride, and the sacrificial insulating layers 118P may be formed of a material different from a material of the interlayer insulating layer 120, selected from among silicon, silicon oxide, silicon carbide, and silicon nitride. In example implementations, the number of the interlayer insulating layers 120 and the sacrificial insulating layers 118P and thicknesses thereof may be varied from the illustrated example.

The gate pad regions GP may be formed by repeating a photolithography process and an etching process for the sacrificial insulating layers 118P and the interlayer insulating layers 120. The gate pad regions GP may be formed in the second region R2, and may be formed such that the sacrificial insulating layers 118P of the upper portion may include a region extending shorter than the sacrificial insulating layers 118P of the lower portion. In the gate pad regions GP, asymmetric step structures may be formed such that upper surfaces and ends of the plurality of sacrificial insulating layers 118P may be exposed upwardly. Sacrificial insulating layers 118P may be further formed on the step structure of the gate pad regions GP such that the sacrificial insulating layers 118P positioned in an uppermost portion in each region may have a relatively great thickness.

Thereafter, the first cell region insulating layer 192 covering the sacrificial insulating layers 118P and the interlayer insulating layers 120 in the first mold structure MSa may be formed. The first vertical sacrificial layers 119a may be formed in positions corresponding to the first channel structures CH, the contact plugs 170 in FIG. 1B, and the dummy vertical structures 175 in FIG. 1C. The first vertical sacrificial layers 119a may be formed by forming holes to penetrate the first mold structure MSa, depositing sacrificial layer material in the holes, and performing a planarization process. The first vertical sacrificial layers 119a may include, for example, carbon or a carbon-based material, but an example implementation thereof is not limited thereto.

The second mold structure MSb, the second vertical sacrificial layers 119b, the third mold structure MSc, and the third vertical sacrificial layers 119c may be formed on the first mold structure MSa in the same manner as the first mold structure MSa and the first vertical sacrificial layers 119a, respectively. The second vertical sacrificial layers 119b may be formed to be connected to the first vertical sacrificial layers 119a, and the third vertical sacrificial layers 119c may be formed to be connected to the second vertical sacrificial layers 119b. In this process, the first to third vertical sacrificial layers 119a, 119b, and 119c formed in the second region R2 may be formed with a width similar to a width in the first region R1, and may be formed with a width less than widths of the contact plugs 170 and the dummy vertical structures 175.

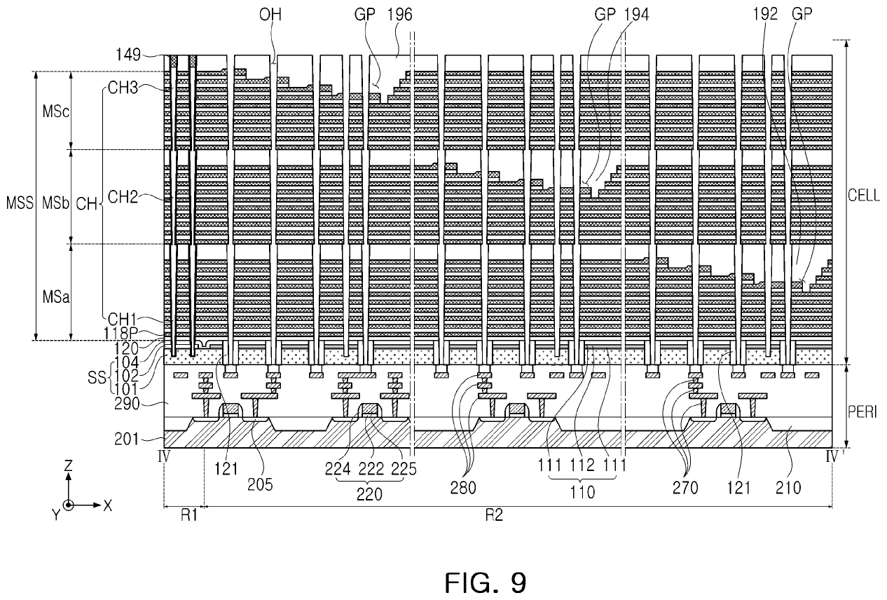

Referring to FIG. 9, channel structures CH penetrating the mold structure MSS may be formed, and first holes OH may be formed.

A mask layer exposing only the first region R1 may be formed. The channel structures CH may be formed by forming lower channel holes by removing the first to third vertical sacrificial layers 119a, 119b, and 119c from the first region R1, and sequentially depositing at least a portion of the gate dielectric layer 145, the channel layer 140, the channel filling insulating layer 147, and the channel pad 149 in the lower channel holes.

The gate dielectric layer 145 may be formed to have a uniform thickness using an ALD or CVD process. In this process, the gate dielectric layer 145 may be formed entirely or partially, and a portion extending vertically along the channel structures CH to the plate layer 101 may be formed in this process. The channel layer 140 may be formed on the gate dielectric layer 145 in the lower channel holes. The channel filling insulating layer 147 may be formed to fill the lower channel holes and may be an insulating material. The channel pad 149 may be formed of a conductive material, for example, polycrystalline silicon.

The first holes OH may be formed by selectively removing the first to third vertical sacrificial layers 119a, 119b, and 119c from the second region R2, and further removing the exposed landing pads 291.

First, a mask layer exposing the first to third vertical sacrificial layers 119a, 119b, and 119c in the second region R2 may be formed, and the first to third vertical sacrificial layers 119a, 119b, and 119c exposed through the mask layer may be selectively removed. When the mask layer is formed to have openings larger than upper surfaces of the third vertical sacrificial layers 119c, the first holes OH may have an enlarged width at upper ends thereof as illustrated in FIG. 9. Circuit interconnection lines 280 may be exposed through bottom surfaces of the first holes OH. In some example implementations, the landing pads 291 may not be removed in this process and may be removed in a subsequent process.

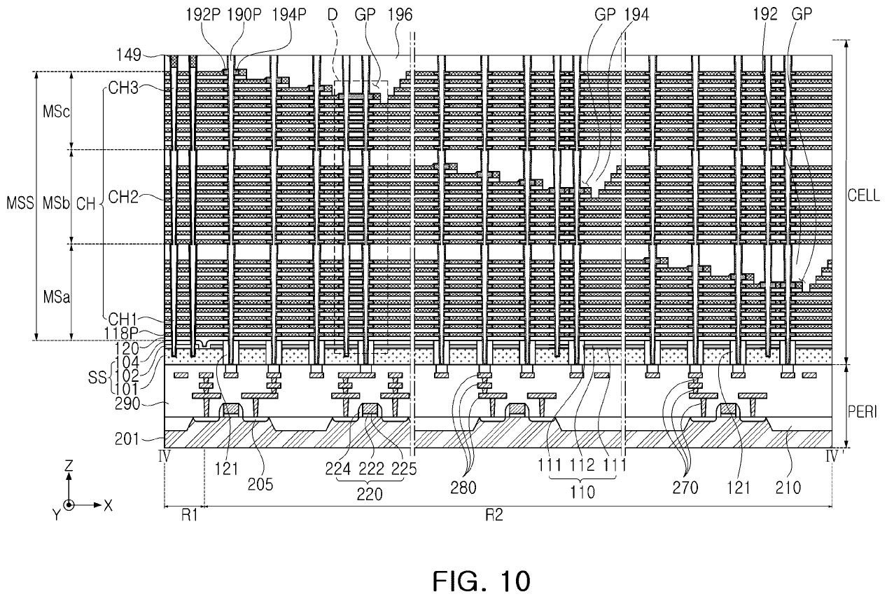

Referring to FIG. 10, after the first holes OH are enlarged in the horizontal direction, the first preliminary insulating liner 192P, the first preliminary insulating pattern 194P, and the vertical sacrificial layer 190P may be formed in the first holes OH.

The first holes OH may be enlarged in the horizontal direction by removing a portion of the sacrificial insulating layers 118P and the interlayer insulating layers 120 exposed through the first holes OH. During the process, the sacrificial insulating layers 118P may be removed relatively longer in the horizontal direction than the interlayer insulating layers 120. Thereafter, the sacrificial insulating layers 118P may be further removed around the first holes OH, thereby forming tunnel portions.

A first preliminary insulating liner 192P may be formed by depositing an insulating material in the first holes OH and tunnel portions. The first preliminary insulating liner 192P may be conformally deposited on internal sidewalls of the tunnel portions, and the first preliminary insulating pattern 194P may fill the tunnel portions on the first preliminary insulating liner 192P in the contact tunnel portions and may be formed on sidewalls of the first holes OH. A vertical sacrificial layer 190P may fill the first holes OH between the sidewalls of the first holes OH. The vertical sacrificial layer 190P may include a different material from that of the first preliminary insulating pattern 194P, and may include, for example, carbon (C).

Referring to region D in FIG. 10, in a process of enlarging the first holes OH in the horizontal direction by removing a portion of the sacrificial insulating layers 118P and the interlayer insulating layers 120 exposed through the first holes OH, the first holes OH spaced apart from each other in the horizontal direction may be connected to each other through the tunnel portions. A distance between central axes of the first holes OH connected through the tunnel portions extending in the third direction (Z-direction) may be less than a distance between central axes of the first holes OH spaced apart from each other in the horizontal direction extending in the third direction (Z-direction).

The first holes OH connected through the tunnel portions may share the first preliminary insulating liner 192P and the first preliminary insulating pattern 194P, and the vertical sacrificial layers 190P extending in the third direction (Z-direction) may be spaced apart from each other in the horizontal direction.

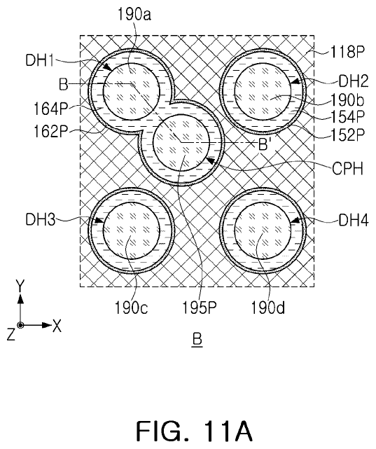

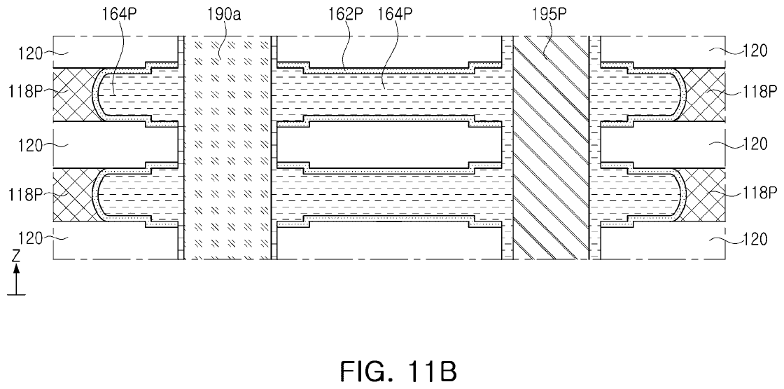

FIGS. 11A to 18B are diagrams illustrating a method of manufacturing a semiconductor device according to an example implementation.

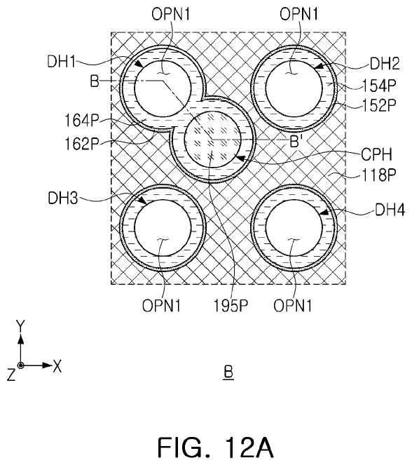

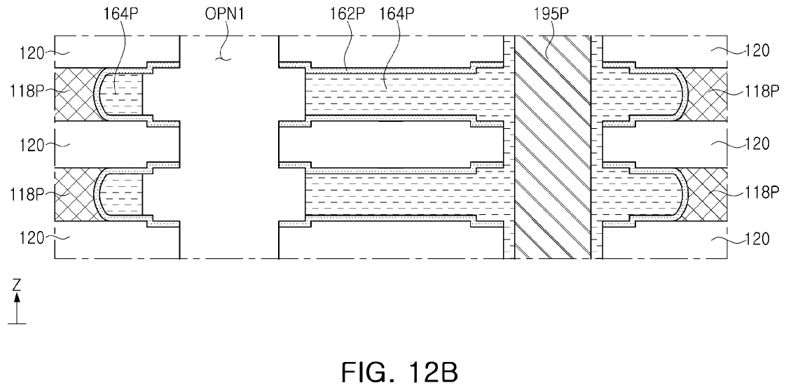

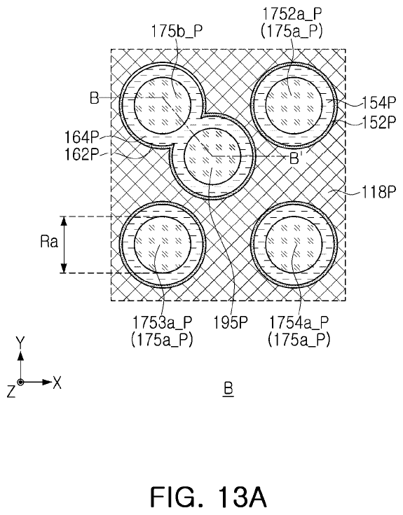

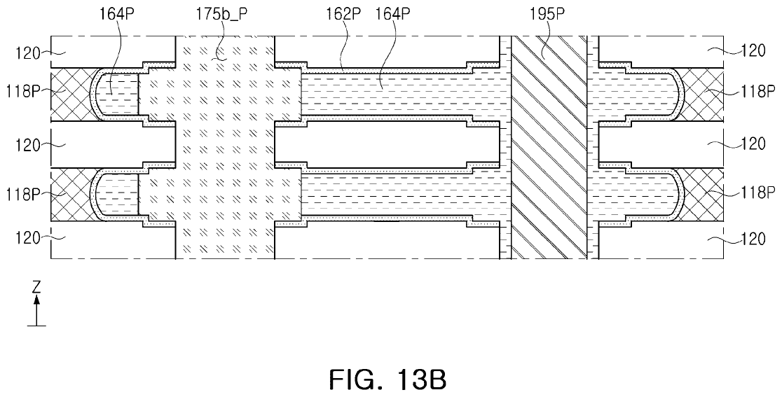

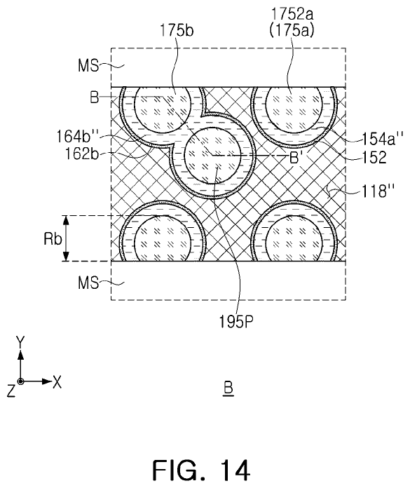

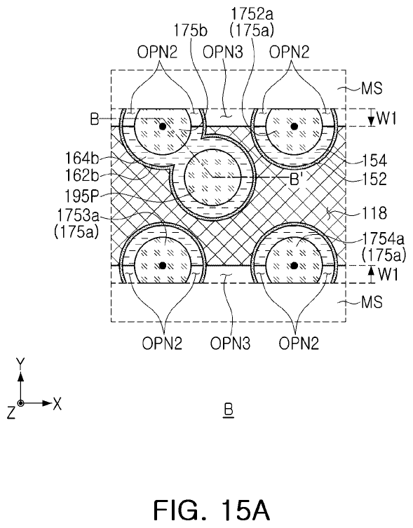

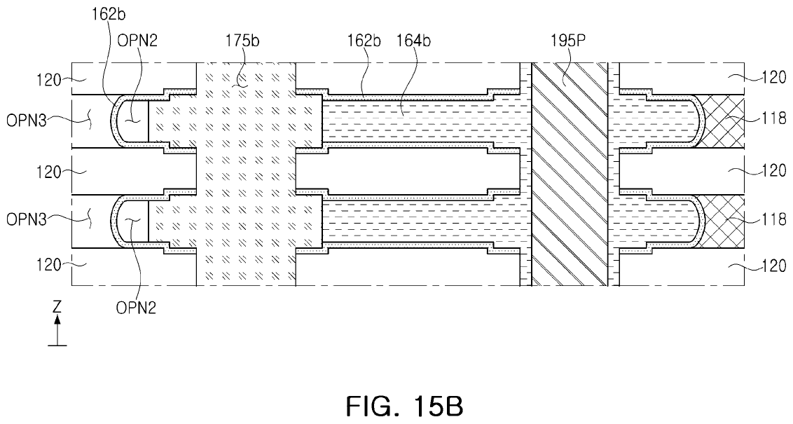

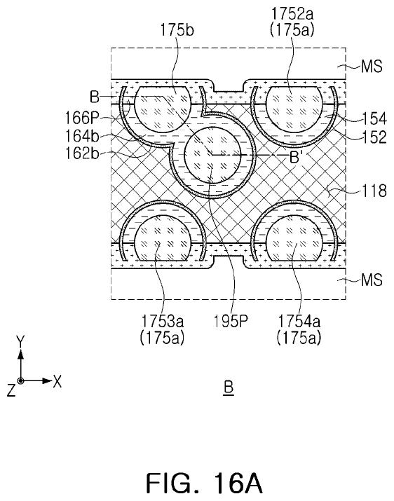

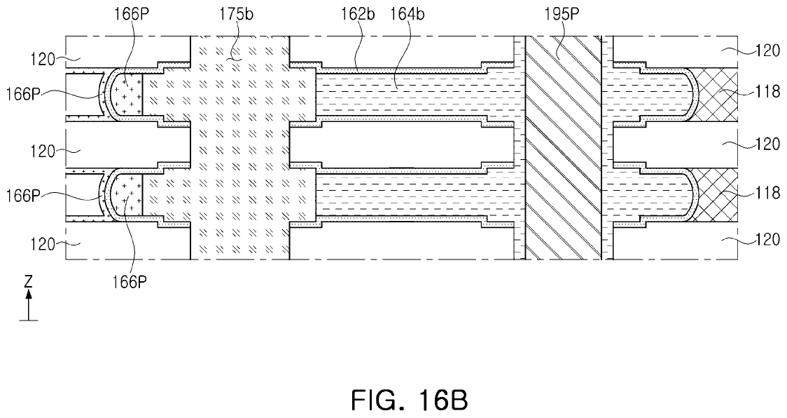

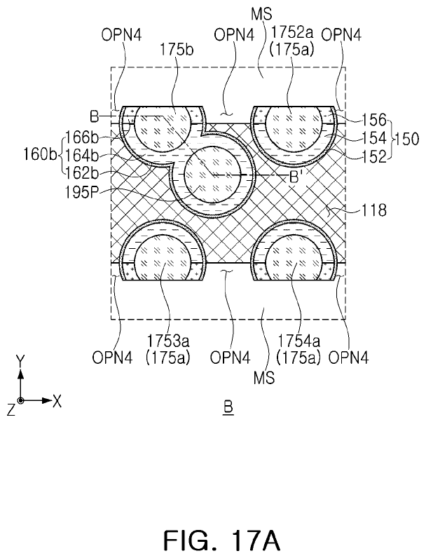

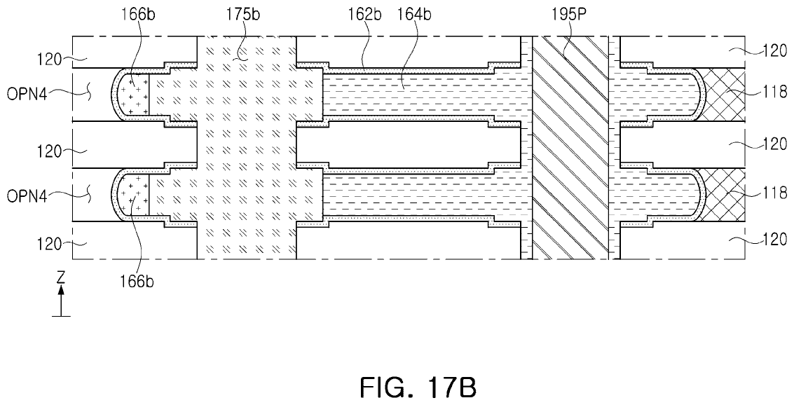

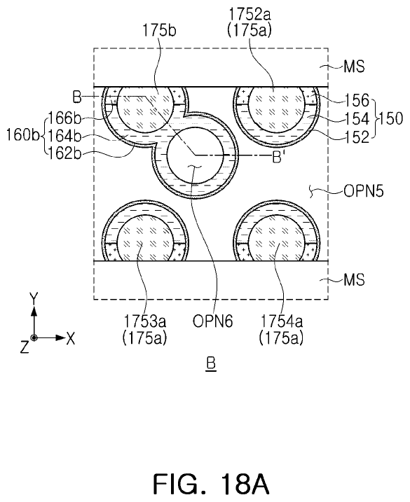

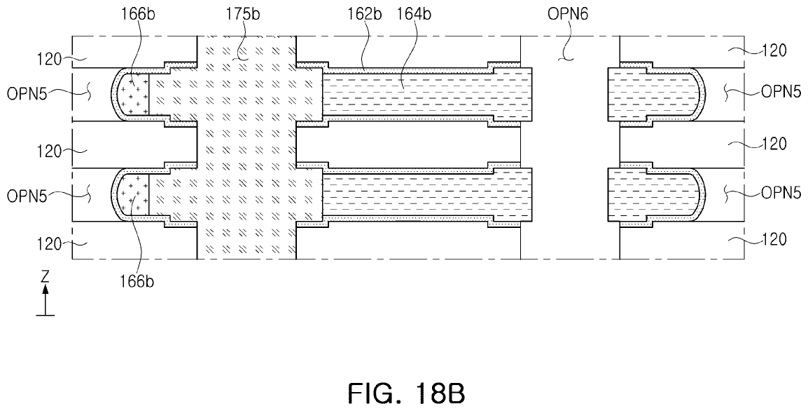

FIG. 11A, FIG. 12A, FIG. 13A, FIG. 14, FIG. 15A, FIG. 16A, FIG. 17A, and FIG. 18A are plan diagrams illustrating processes after the process of forming first holes sharing the first preliminary insulating liner 192P and the first preliminary insulating pattern 194P in FIG. 10 and first holes spaced apart from each other in the horizontal direction, respectively, and are plan diagrams corresponding to FIG. 5.

FIG. 11B, FIG. 12B, FIG. 13B, FIG. 15B, FIG. 16B, FIG. 17B, and FIG. 18B are cross-sectional diagrams taken along line B-B′ of the semiconductor device in FIG. 11A, FIG. 12A, FIG. 13A, FIG. 15A, FIG. 16A, FIG. 17A, and FIG. 18A, and are cross-sectional diagrams corresponding to FIG. 6A.

Referring to FIGS. 11A and 11B, the first holes OH sharing the first preliminary insulating liner 192P and the first preliminary insulating pattern 194P in FIG. 10 may be referred to as a first contact hole CPH and a first dummy hole DH1, and the first preliminary insulating liner 192P in the first contact hole CPH and the first dummy hole DH1 may be referred to as a second preliminary contact insulating liner 162P, and the first preliminary insulating pattern 194P may be referred to as a second preliminary contact insulating pattern 164P. The vertical sacrificial layer 190P in the first contact hole CPH may be referred to as a first contact vertical sacrificial layer 195P. The vertical sacrificial layer 190P in the first dummy hole DH1 may be referred to as a first dummy sacrificial layer 190a. The first holes OH spaced apart from each other in FIG. 10 may be referred to as second, third, and fourth dummy holes DH2, DH3, and DH4, and the first preliminary insulating liner 192P and the first preliminary insulating pattern 194P formed in the first holes OH spaced apart from each other may be referred to as preliminary dummy insulating liner 152P and first preliminary dummy insulating pattern 154P in the second, third, and fourth dummy holes DH2, DH3, and DH4, respectively. The second dummy sacrificial layer 190b in the second dummy hole DH2, the third dummy sacrificial layer 190c in the third dummy hole DH3, and the fourth dummy sacrificial layer 190d in the fourth dummy hole DH4 may correspond to the vertical sacrificial layer 190P in the first holes OH1 spaced apart from each other.

The first contact hole CPH may correspond to the second contact plug 170b in FIG. 5, the first dummy hole DH1 may correspond to the second dummy vertical structure 175b in FIG. 5, and the second, third, and fourth dummy holes DH2, DH3, and DH4 may correspond to the 1-2 dummy vertical structure 1752a, the 1-3 dummy vertical structure 1753a, and the 1-4 dummy vertical structure 1754a in FIG. 5.

Since the first contact hole CPH is disposed such that a spacing distance with the first dummy hole DH1 is less than a spacing distance with the second, third, and fourth dummy holes DH2, DH3, and DH4, the first holes OH in FIG. 10 may be connected in the process of being enlarged in the horizontal direction and may share the second preliminary contact insulating liner 162P and the second preliminary contact insulating pattern 164P. Accordingly, the first contact hole CPH and the first dummy hole DH1 may be physically connected to each other.

The second, third, and fourth dummy holes DH2, DH3, and DH4 may be spaced apart from each other in the horizontal direction, and the preliminary dummy insulating liner 152P and the first preliminary dummy insulating pattern 154P disposed in the tunnel portions of the second, third, and fourth dummy holes DH2, DH3, and DH4, respectively, may also be spaced apart from each other in the horizontal direction. The second preliminary contact insulating liner 162P and the preliminary dummy insulating liners 152P may be spaced apart from each other in the horizontal direction, and sacrificial insulating layers 118P may be formed between the preliminary dummy insulating liners 152P and the second preliminary contact insulating liner 162P.

Referring to FIGS. 12A and 12B, the first openings OPN1 may be formed by removing the first dummy sacrificial layer 190a in the first dummy hole DH1, the second dummy sacrificial layer 190b in the second dummy hole DH2, the third dummy sacrificial layer 190c in the third dummy hole DH3, and the fourth dummy sacrificial layer 190d in the fourth dummy hole DH4. The first to fourth dummy sacrificial layers 190a to 190d may be removed by a wet etching process.

Referring to FIGS. 13A and 13B, preliminary dummy vertical structures 175a_P and 175b_P may be formed by filling the first openings OPN1 with an insulating material. The first preliminary dummy vertical structures 175a_P may be formed as dummy vertical structures surrounded by a preliminary dummy insulating liner 152P and a first preliminary dummy insulating pattern 154P by filling the second dummy hole DH2, the third dummy hole DH3, and the fourth dummy hole DH4 with the insulating material. The first preliminary dummy vertical structures 175a_P may include 1-2 preliminary dummy vertical structures 1752a_P formed in the second dummy hole DH2, 1-3 preliminary dummy vertical structures 1753a_P formed in the third dummy hole DH3, and 1-4 preliminary dummy vertical structures 1754a_P formed in the fourth dummy hole DH4.

The second preliminary dummy vertical structure 175b_P may be formed as a dummy vertical structure surrounded by the second preliminary contact insulating liner 162P and the second preliminary contact insulating pattern 164P by filling the insulating material in the first dummy hole DH1.

Referring to FIG. 13A and FIG. 14, by removing, in the vertical direction, a portion extending in the first direction (X-direction), and overlapping a portion of the sacrificial insulating layers 118P, a portion of the 1-2 preliminary dummy vertical structure 1752a_P, a portion of the first preliminary dummy insulating pattern 154P surrounding the 1-2 preliminary dummy vertical structure 1752a_P, a portion of the preliminary dummy insulating liner 152P surrounding the first preliminary dummy insulating pattern 154P, a portion of the second preliminary dummy vertical structure 175b_P, a portion of the second preliminary contact insulating pattern 164P surrounding the second preliminary dummy vertical structure 175b_P, and a portion of the second preliminary contact insulating liner 162P surrounding the second preliminary contact insulating pattern 164P, when viewed on a plane, an isolation region MS (e.g., the first isolation region) may be formed on an upper side of the first contact vertical sacrificial layer 195P.

By removing, in the vertical direction, a portion extending in the first direction (X-direction), and overlapping a portion of the sacrificial insulating layers 118P, a portion of the 1-3 and 1-4 preliminary dummy vertical structures 1753a_P and 1754a_P, a portion of the first preliminary dummy insulating pattern 154P surrounding the 1-3 and 1-4 preliminary dummy vertical structures 1753a_P and 1754a_P, and a portion of the preliminary dummy insulating liner 152P surrounding the first preliminary dummy insulating pattern 154P, when viewed on a plane, an isolation region MS (e.g., second isolation region) may be formed on a lower side of the first contact vertical sacrificial layer 195P.

As the isolation regions MS are formed, a portion of the first preliminary dummy vertical structure 175a_P may be removed such that a first dummy vertical structure 175a may be formed, and a portion of the second preliminary dummy vertical structure 175b_P may be removed such that a second dummy vertical structure 175b may be formed.

As the isolation regions MS are formed, the second preliminary dummy vertical structure 175b_P may be formed as the second dummy vertical structure 175b, and the 1-2 preliminary dummy vertical structure 1752a_P may be formed as the 1-2 dummy vertical structure 1752a. The 1-3 preliminary dummy vertical structure 1753a_P may be formed as the 1-3 dummy vertical structure 1753a, and the 1-4 preliminary dummy vertical structure 1754a_P may be formed as the 1-4 dummy vertical structure 1754a.

Referring to FIG. 13A and FIG. 14, when viewed on a plane, a maximum width of each of the first preliminary dummy vertical structures 175a_P and the second preliminary dummy vertical structure 175b_P may have a first size Ra.

When viewed on a plane, a maximum width of each of the first dummy vertical structures 175a and the second dummy vertical structure 175b may have a second size Rb less than the first size Ra. The second size Rb may be larger than half the first size Ra.

The first preliminary dummy insulating pattern 154P and the preliminary dummy insulating liner 152P may be partially cut out and may be formed as a first dummy insulating pattern 154a″ and a dummy insulating liner 152 surrounding the first dummy vertical structures 175a, respectively.

The second preliminary contact insulating pattern 164P and the second preliminary contact insulating liner 162P may be partially cut out and may be formed as a second contact insulating pattern 164b″ and a second contact insulating liner 162b surrounding the second dummy vertical structures 175b, respectively.

Referring to FIG. 15A and FIG. 15B, a first dummy insulating pattern 154a″ disposed between the first dummy vertical structures 175a and the dummy insulating liner 152 may be removed by a first width W1, and the second contact insulating pattern 164b″ formed between the second dummy vertical structures 175b and the second contact insulating liner 162b may be removed by the first width W1, such that second openings OPN2 may be formed. The first dummy insulating pattern 154 and the 2-1 contact insulating pattern 164b may be exposed through the second openings OPN2.

The sacrificial insulating layers 118″ between the dummy insulating liner 152 and the second contact insulating liner 162b may be removed by the first width W1, such that third openings OPN3 may be formed, and the sacrificial insulating layers 118 may be exposed through the third openings OPN3.

By etching the first width W1 in the horizontal direction through a pull-back process or etching process with respect to a side surface of the first dummy insulating pattern 154a″, a side surface of the second contact insulating pattern 164b″, and a side surface of the sacrificial insulating layers 118P exposed through the isolation regions MS in FIG. 14, second openings OPN2 and third openings OPN3 may be formed. The etching degree of a side surface of the first dummy insulating pattern 154a″, a side surface of the second contact insulating pattern 164b″, and a side surface of the sacrificial insulating layers 118″ may be controlled by controlling the pull-back process time. The first width W1 may be less than half the first size Ra in FIG. 13A.

A portion of the first dummy vertical structures 175a and a portion of the dummy insulating liner 152 may be exposed through the second openings OPN2 and the third openings OPN3 by a pull-back process for a side surface of the first dummy insulating pattern 154a″ and a side surface of the sacrificial insulating layers 118″ exposed through the isolation regions MS.

A portion of the second dummy vertical structure 175b and a portion of the second contact insulating liner 162b may be exposed through the second openings OPN2 and the third openings OPN3 by a pull-back process for a side surface of the second contact insulating pattern 164b″ and a side surface of the sacrificial insulating layers 118″ exposed through the isolation regions MS.

Referring to FIGS. 16A and 16B, an insulating pattern 166P may be formed in the second openings OPN2 and the third openings OPN3.

Since a width of each of the second openings OPN2 is relatively less than a width of each of the third openings OPN3, the insulating pattern 166P may fill the second openings OPN2 and may be formed be conformally along an internal sidewall of the third openings OPN3. The insulating pattern 166P may be silicon oxide.

Referring to FIGS. 17A and 17B, a planarization process may be performed such that a side surface of the first dummy vertical structures 175a and a side surface of the second dummy vertical structures 175b may be exposed, and the fourth openings OPN4 may be formed by removing the insulating pattern 166P formed between the dummy insulating liner 152 and the second contact insulating liner 162b. The insulating pattern 166P may be disposed on a side surface of the 2-1 contact insulating pattern 164b, and may be formed as 2-1 contact insulating patterns 164b, thereby preventing the 2-1 contact insulating pattern 164b from being exposed. Accordingly, the second contact insulating structures 160b including the 2-1 contact insulating pattern 164b, the 2-2 contact insulating patterns 166b, and the second contact insulating liner 162b may be formed.

The insulating pattern 166P may be disposed on a side surface of the first dummy insulating pattern 154 and may be formed as second dummy insulating patterns 156, thereby preventing the side surface of the first dummy insulating pattern 154 from being exposed. Accordingly, a dummy insulating structure 150 including the first dummy insulating pattern 154, the second dummy insulating patterns 156, and the dummy insulating liner 152 may be formed.

Referring to FIGS. 18A and 18B, a fifth opening OPN5 may be formed by removing the sacrificial insulating layers 118, and a sixth opening OPN6 may be formed by removing the first contact vertical sacrificial layer 195P. In the process of removing the sacrificial insulating layers 118, the 2-1 contact insulating pattern 164b may not be removed by the 2-2 contact insulating patterns 166b, and the first dummy insulating pattern 154 may not be removed by the second dummy insulating pattern 156. Accordingly, in the process of removing the sacrificial insulating layers 118 and replacing the layers with a conductive material, the 2-1 contact insulating patterns 164b may surround the side surface of the second contact plug 170b and the side surface of the second dummy vertical structure 175b, such that the second contact plug 170b and the second dummy vertical structure 175b may be prevented from being conductive through the conductive material.

Thereafter, referring to FIG. 1B and FIG. 5, a conductive material may be formed in the fifth opening OPN5, thereby forming a gate electrode 130, and a conductive material may be formed in the sixth opening OPN6, thereby forming a second contact plug 170b. By forming studs 180 connected to upper ends of the contact plugs 170 and the channel structures CH, a semiconductor device 100 may be manufactured.

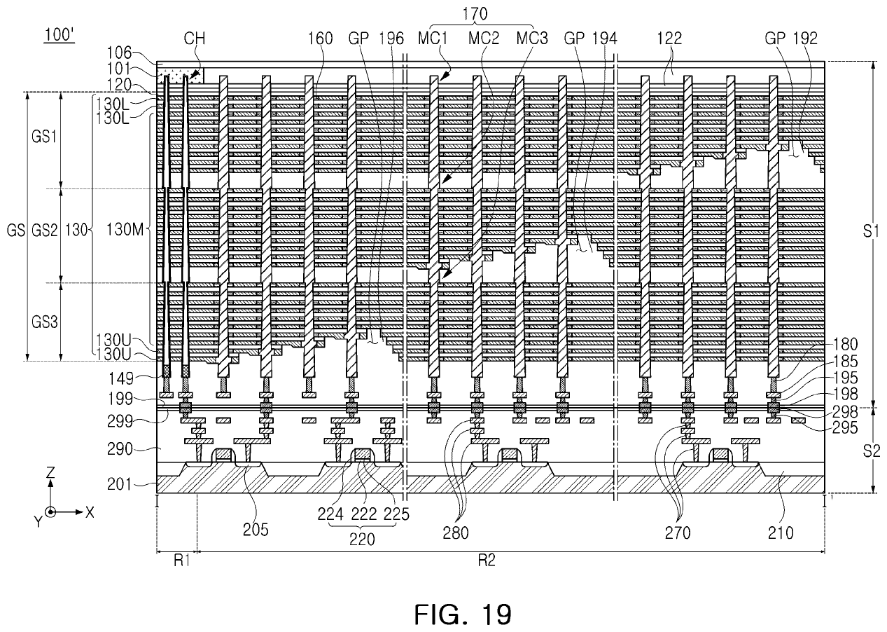

FIG. 19 is a cross-sectional diagram illustrating a semiconductor device taken along line I-I′ in FIG. 1A according to an example implementation.

Referring to FIG. 19, a semiconductor device 100′ may include a memory cell structure S1 and a peripheral circuit structure S2 bonded to each other by a wafer bonding method.

The description of the peripheral circuit region PERI described above with reference to FIG. 1B may be applied to the peripheral circuit structure S2. The peripheral circuit structure S2 may further include second bonding vias 295 and second bonding metal layers 298, and a second bonding insulating layer 299, which are bonding structures. The second bonding vias 295 may be connected to circuit interconnection lines 280 in an uppermost portion. At least a portion of the second bonding metal layer 298 may be connected to the second bonding vias 295. The second bonding metal layer 298 may be connected to the first bonding metal layers 198 of the memory cell structure S1. The second bonding metal layers 298 may provide an electrical connection path for bonding the memory cell structure S1 and the peripheral circuit structure S2 together with the first bonding metal layers 198. In another example, a portion of the second bonding metal layers 298 may not be connected to circuit interconnection lines 280 of the lower portion and may be disposed only for bonding.

The second bonding vias 295 and the second bonding metal layers 298 may include a conductive material, for example, copper (Cu). The second bonding insulating layer 299 may be disposed around the second bonding metal layers 298. The second bonding insulating layer 299 may also function as a diffusion barrier for the second bonding metal layers 298 and may include, for example, at least one of SiN, SiON, SiCN, SiOC, SiOCN, and SiO.

In case there is no other description for the memory cell structure S1, the description of the memory cell region CELL described above with reference to FIG. 1B may be applied. The memory cell structure S1 may further include a substrate insulating layer 122, cell interconnection lines 185, a bonding structure of the first bonding vias 195, first bonding metal layers 198 and a first bonding insulating layer 199. In an example, the memory cell structure S1 may further include a passivation layer 106 covering an upper surface of the plate layer 101 and an upper surface of the substrate insulating layers 122.

The substrate insulating layer 122 may be disposed above the gate structure GS, disposed between the plate layer 101 and the gate structure GS on the first region R1, and disposed at the same level as the plate layer 101 on the second region R2. The channel structure CH may penetrate the gate structure GS and the substrate insulating layer 122 in the first region R1 and may be positioned in the plate layer 101.

The substrate insulating layer 122 may be disposed under the plate layer 101 on the first region R1, extends from the first region R1 to the second region R2, and may be disposed on the same level as the plate layer 101 on the second region R2.

The cell interconnection lines 185 may be connected to the studs 180. However, in example implementations, the number of layers and arrangement of the plugs and the interconnection lines included in the cell interconnection structure may be varied. The cell interconnection lines 185 may be formed of a conductive material, and may include at least one of tungsten (W), aluminum (Al), and copper (Cu), for example.

The first bonding vias 195 and the first bonding metal layers 198 may be disposed below the cell interconnection lines 185 in the lowermost portion. The first bonding vias 195 may connect the cell interconnection lines 185 to the first bonding metal layers 198, and the first bonding metal layers 198 may be bonded to the second bonding metal layers 298 of the peripheral circuit structure S2. The first bonding insulating layer 199 may be bonded to the second bonding insulating layer 299 of the peripheral circuit structure S2. The first bonding vias 195 and the first bonding metal layers 198 may include a conductive material, for example, copper (Cu). The first bonding insulating layer 199 may include at least one of, for example, SiO, SiN, SiCN, SiOC, SiON, and SiOCN.

The first and second semiconductor structures S1 and S2 may be bonded to each other by bonding between the first bonding metal layers 198 and the second bonding metal layers 298 and by bonding between the first bonding insulating layer 199 and the second bonding insulating layer 299. The bonding between the first bonding metal layers 198 and the second bonding metal layers 298 may be, for example, copper (Cu)-copper (Cu) bonding, and the bonding between the first bonding insulating layer 199 and the second bonding insulating layer 299 may be, for example, dielectric-dielectric bonding, such as SiCN—SiCN bonding. The first and second semiconductor structures S1 and S2 may be bonded to each other by hybrid bonding including copper (Cu)-copper (Cu) bonding and dielectric-dielectric bonding.

The passivation layer 106 may be disposed on an upper surface of the plate layer 101 and may protect the semiconductor device 100′. The passivation layer 106 may include at least one of an insulating material, for example, silicon oxide, silicon nitride, and silicon carbide. The substrate insulating layer 122 may be widely disposed in the first region R1 and the second region R2 to cover upper ends of the contact plugs 170. However, in example implementations, the arrangement of the substrate insulating layer 122 may be varied in a range in which the contact plugs 170 are electrically isolated from the plate layer 101.

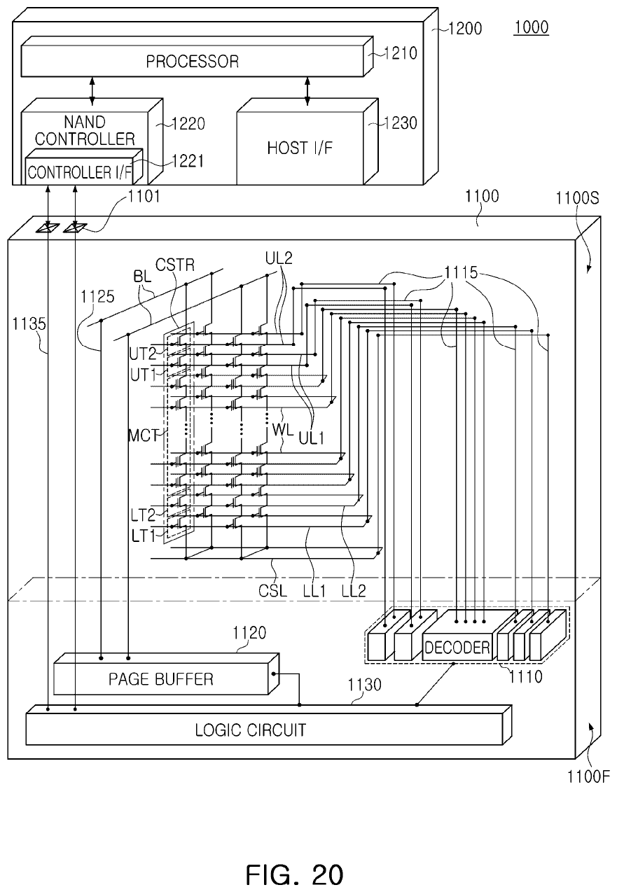

FIG. 20 is a diagram illustrating a data storage system including a semiconductor device according to an example implementation.

Referring to FIG. 20, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example implementation with reference to FIGS. 1A to 1D. The semiconductor device 1100 may include a first structure 1100F and a second structure 1100S on the first structure 1100F. In the example implementations, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example implementations.

In the example implementations, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In the example implementations, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 or the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example implementations, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

According to the aforementioned example implementations, a semiconductor device and data storage system including the same may include a contact plug, a dummy vertical structure adjacent to the contact plug, and a contact insulating structure shared by the contact plug and the dummy vertical structure, and the contact insulating structure may include a first contact insulating pattern in contact with the contact plug and a portion of the dummy vertical structure and second contact insulating patterns in contact with the other portion of the dummy vertical structure. Accordingly, by preventing the first contact insulating pattern from being removed during the manufacturing process by the second contact insulating patterns of the contact insulating structure shared by the contact plug and the dummy vertical structure, a semiconductor device having improved reliability and a data storage system including the same may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a first semiconductor structure including a substrate, circuit devices on the substrate, and circuit interconnections on the circuit devices; and
a second semiconductor structure on the first semiconductor structure, the second semiconductor structure having a first region and a second region,
wherein the second semiconductor structure includes:
a plate layer;
gate electrodes stacked and spaced apart from each other on the plate layer in a vertical direction perpendicular to an upper surface of the plate layer, the gate electrodes extending to different lengths in a first direction intersecting the vertical direction in the second region, and each of the gate electrodes including a pad region, an upper surface of the pad region being exposed;
interlayer insulating layers disposed alternately with the gate electrodes;
a channel structure extending through the gate electrodes and the interlayer insulating layers in the first region, the channel structure extending in the vertical direction;
contact plugs extending through the pad region of each of the gate electrodes in the second region, the contact plugs extending in the vertical direction, and the contact plugs electrically connecting the gate electrodes to at least one corresponding circuit interconnection of the circuit interconnections;
dummy vertical structures extending through the gate electrodes and the interlayer insulating layers in the second region, the dummy vertical structures extending in the vertical direction and being spaced apart from the contact plugs in a horizontal direction; and
contact insulating structures disposed alternately with the interlayer insulating layers, the contact insulating structures being at corresponding pad regions of the gate electrodes, the contact insulating structures surrounding the contact plugs,
wherein the pad region of each of the gate electrodes includes a first pad region, and a first contact plug of the contact plugs extends through the first pad region,
wherein the dummy vertical structures include a first dummy vertical structure adjacent to the first contact plug, and
wherein the contact insulating structures include first contact insulating structures in contact with the first contact plug and the first dummy vertical structure, the first contact insulating structures being at the first pad region.

2. The semiconductor device of claim 1,
wherein each of the first contact insulating structures includes:
a first contact insulating pattern in contact with the first contact plug and a first portion of the first dummy vertical structure;
second contact insulating patterns surrounding second portions of the first dummy vertical structure, the second portions of the first dummy vertical structure being connected to the first portion of the first dummy vertical structure; and
a contact insulating liner covering an external side surface of the first contact insulating pattern and external side surfaces of the second contact insulating patterns,
wherein the first contact insulating pattern includes a first insulating material, and
wherein the second contact insulating patterns include a second insulating material different from the first insulating material.

3. The semiconductor device of claim 2,
wherein the first contact insulating pattern has a first area in contact with the first portion of the first dummy vertical structure,
wherein each of the second contact insulating patterns has a second area in contact with a respective second portion of the second portions of the first dummy vertical structure, and
wherein the second area is smaller than the first area.

4. The semiconductor device of claim 1,
wherein the dummy vertical structures include a second dummy vertical structure adjacent to the first contact plug, the second dummy vertical structure being spaced apart from the first dummy vertical structure in the horizontal direction,
wherein the second semiconductor structure includes dummy insulating structures disposed alternately with the interlayer insulating layers, the dummy insulating structures surrounding the second dummy vertical structure, and
wherein the dummy insulating structures are spaced apart from the first contact insulating structures in the horizontal direction, respectively.

5. The semiconductor device of claim 4,
wherein the first contact plug and the first dummy vertical structure are spaced apart from each other by a first distance along the horizontal direction, and
wherein the first contact plug and the second dummy vertical structure are spaced apart from each other by a second distance along the horizontal direction, the second distance being greater than the first distance.

6. The semiconductor device of claim 4, wherein the gate electrodes are between the first contact insulating structures and the dummy insulating structures.

7. The semiconductor device of claim 4, wherein each of the dummy insulating structures includes:
a first dummy insulating pattern surrounding a third portion of the second dummy vertical structure;
second dummy insulating patterns surrounding fourth portions of the second dummy vertical structure, the fourth portions of the second dummy vertical structure being connected to the third portion of the second dummy vertical structure; and
a dummy insulating liner surrounding the first dummy insulating pattern and the second dummy insulating patterns.

8. The semiconductor device of claim 1, comprising:
a first isolation structure extending through the gate electrodes in the first direction; and
a second isolation structure extending through the gate electrodes, the second isolation structure being spaced apart from the first isolation structure in a second direction intersecting the vertical direction and the first direction,
wherein the first contact plug is between the first isolation structure and the second isolation structure, and
wherein the first dummy vertical structure is in contact with the first isolation structure.

9. The semiconductor device of claim 1,
wherein the dummy vertical structures include a second dummy vertical structure adjacent to the first contact plug, the second dummy vertical structure being spaced apart from the first dummy vertical structure in the first direction, and
wherein the first contact insulating structures are in contact with the second dummy vertical structure.

10. The semiconductor device of claim 9,
wherein each of the first contact insulating structures includes:
a first contact insulating pattern in contact with the first contact plug, a first portion of the first dummy vertical structure, and a third portion of the second dummy vertical structure;
second contact insulating patterns surrounding second portions of the first dummy vertical structure, the second portions of the first dummy vertical structure being connected to the first portion of the first dummy vertical structure;
third contact insulating patterns surrounding fourth portions of the second dummy vertical structure, the fourth portions of the second dummy vertical structure being connected to the third portion of the second dummy vertical structure; and
a contact insulating liner covering an external side surface of the first contact insulating pattern, external side surfaces of the second contact insulating patterns, and external side surfaces of the third contact insulating patterns,
wherein the first contact insulating pattern includes a first insulating material, and
wherein the second contact insulating patterns and the third contact insulating patterns include a second insulating material different from the first insulating material.

11. The semiconductor device of claim 1,
wherein the dummy vertical structures include an insulating material, and
wherein the contact plugs include a conductive material.

12. A semiconductor device comprising:
a stack pattern having a memory cell array region and a staircase region;
a stack structure extending from the memory cell array region to the staircase region, the stack structure being on the stack pattern, wherein the stack structure includes interlayer insulating layers and gate electrodes disposed alternately in a vertical direction, and the gate electrodes include gate contact pads, the gate contact pads defining a staircase in the staircase region;
a channel structure extending through the stack structure in the memory cell array region in the vertical direction;
a first contact plug extending through the gate electrodes and the interlayer insulating layers in the staircase region;
a first dummy vertical structure extending through the gate electrodes and the interlayer insulating layers in the staircase region, the first dummy vertical structure being adjacent to the first contact plug;
first contact insulating structures disposed alternately with the interlayer insulating layers, the first contact insulating structures surrounding the first contact plug; and
first dummy insulating structures disposed alternately with the interlayer insulating layers, the first dummy insulating structures surrounding the first dummy vertical structure,
wherein the first contact insulating structures are spaced apart from the first dummy insulating structures,
wherein each of the first dummy insulating structures includes
a first dummy insulating pattern surrounding a first portion of the first dummy vertical structure,
a second dummy insulating pattern surrounding a second portion of the first dummy vertical structure, the second portion of the first dummy vertical structure extending from the first portion, and
a dummy insulating liner surrounding the first dummy insulating pattern and the second dummy insulating pattern,
wherein the first dummy insulating pattern includes a first insulating material, and
wherein the second dummy insulating pattern includes a second insulating material different from the first insulating material.

13. The semiconductor device of claim 12,
wherein each of the first contact insulating structures includes a first contact insulating pattern surrounding the first contact plug and a first contact insulating liner surrounding the first contact insulating pattern, and
wherein the first contact insulating pattern includes the first insulating material.

14. The semiconductor device of claim 13, wherein the first dummy insulating pattern is closer to the first contact insulating pattern than the second dummy insulating pattern.

15. The semiconductor device of claim 14, comprising:
a second contact plug extending through the gate electrodes and the interlayer insulating layers in the staircase region;
a second dummy vertical structure extending through the gate electrodes and the interlayer insulating layers in the staircase region, the second dummy vertical structure being adjacent to the second contact plug; and
second contact insulating structures disposed alternately with the interlayer insulating layers, the second contact insulating structures surrounding the second contact plug and the second dummy vertical structure.

16. The semiconductor device of claim 15,
wherein each of the second contact insulating structures includes:
a third contact insulating pattern in contact with the second contact plug and a third portion of the second dummy vertical structure;
a fourth contact insulating pattern in contact with a fourth portion of the second dummy vertical structure, the fourth portion of the second dummy vertical structure extending from the third portion; and
a second contact insulating liner surrounding the third contact insulating pattern and the fourth contact insulating pattern,
wherein the third contact insulating pattern includes the first insulating material, and
wherein the fourth contact insulating pattern includes the second insulating material.

17. The semiconductor device of claim 15,
wherein the first contact plug and the first dummy vertical structure are spaced apart from each other by a first distance along a horizontal direction, and
wherein the second contact plug and the second dummy vertical structure are spaced apart from each other by a second distance along the horizontal direction, the second distance being less than the first distance.

18. The semiconductor device of claim 12, comprising:
a second dummy vertical structure extending through the gate electrodes and the interlayer insulating layers in the staircase region, the second dummy vertical structure being adjacent to the first contact plug, the second dummy vertical structure being spaced apart from the first dummy vertical structure in a first direction intersecting the vertical direction;
a third dummy vertical structure spaced apart from the first dummy vertical structure in a second direction intersecting the vertical direction and the first direction;
second dummy insulating structures disposed alternately with the interlayer insulating layers, the second dummy insulating structures surrounding the second dummy vertical structure; and
third dummy insulating structures disposed alternately with the interlayer insulating layers, the third dummy insulating structures surrounding the third dummy vertical structure,
wherein the second dummy insulating structures and the third dummy insulating structures are spaced apart from the first contact insulating structures.

19. The semiconductor device of claim 18, comprising:
isolation structures extending through the gate electrodes in the first direction, and being spaced apart from each other in the second direction,
wherein the isolation structures include a first isolation structure and a second isolation structure that is spaced apart from the first isolation structure in the second direction,
wherein the first contact plug is between the first and second isolation structures,
wherein the first dummy vertical structure and the second dummy vertical structure are in contact with the first isolation structure, and
wherein the third dummy vertical structure is in contact with the second isolation structure.

20. A data storage system comprising:
a semiconductor storage device comprising:
a first semiconductor structure including circuit devices and circuit interconnections electrically connected to the circuit devices,
a second semiconductor structure on the first semiconductor structure, the second semiconductor structure including a first region and a second region, and
an input/output pad electrically connected to the circuit devices; and
a controller electrically connected to the semiconductor storage device through the input/output pad, the controller electrically being configured to control the semiconductor storage device,
wherein the second semiconductor structure includes:
a plate layer;
gate electrodes stacked and spaced apart from each other in a vertical direction on an upper surface of the plate layer, the gate electrodes extending to different lengths in a first direction intersecting the vertical direction in the second region, and each of the gate electrodes including a pad region, an upper surface of the pad region being exposed;
interlayer insulating layers disposed alternately with the gate electrodes;
channel structures extending through the gate electrodes and the interlayer insulating layers in the first region, the channel structures extending in the vertical direction;
contact plugs extending through the pad region of each of the gate electrodes in the second region, the contact plugs extending in the vertical direction, the contact plugs electrically connecting the gate electrodes to at least one corresponding circuit interconnection of the circuit interconnections;
dummy vertical structures extending through the gate electrodes and the interlayer insulating layers in the second region, the dummy vertical structures extending in the vertical direction and being spaced apart from the contact plugs in a horizontal direction intersecting the vertical direction; and
contact insulating structures disposed alternately with the interlayer insulating layers, the contact insulating structures being at corresponding pad regions of the gate electrodes, the contact insulating structures surrounding the contact plugs,
wherein the pad region of each of the gate electrodes includes a first pad region, and a first contact plug of the contact plugs extends through the first pad region,
wherein the dummy vertical structures include a first dummy vertical structure adjacent to the first contact plug, and
wherein each of the contact insulating structures includes
a first contact insulating pattern in contact with the first contact plug and a first portion of the first dummy vertical structure at the first pad region, and
second contact insulating patterns in contact with second portions of the first dummy vertical structure, the second portions of the first dummy vertical structure being connected to the first portion of the first dummy vertical structure.
